(19) United States
(12) Patent Application Publication
(10) Pub. No.: US 2026/0150426 A1
(43) Pub. Date: May 28, 2026

(54) SEMICONDUCTOR DEVICE

(71) Applicant: Sony Semiconductor Solutions Corporation, Kanagawa (JP)

(72) Inventors: Yasuhiro Nonaka, Kanagawa (JP); Kentaro Akiyama, Kanagawa (JP); Toshiaki Ono, Kanagawa (JP)

(21) Appl. No.: 19/112,489

(22) PCT Filed: Sep. 13, 2023
(86) PCT No.: PCT/JP2023/033323

§ 371 Date: Mar. 17, 2025

(30) Foreign Application Priority Data
Oct. 19, 2022 (JP) 2022-167873

(51) Int. Cl. H10F 39/00

(52) U.S. Cl. CPC H10F 39/809; H10F 39/018; H10F 39/811

(57) ABSTRACT

A semiconductor device includes: a first semiconductor element including a pixel region in which a plurality of pixels is arranged on one surface; a second semiconductor element packaged in a region different from the pixel region on the one surface, and including a first circuit that is electrically coupled to the pixel; and a third semiconductor element packaged on the second semiconductor element on a side opposite to the first semiconductor element, and including a second circuit that is electrically coupled to the pixel.

### TECHNICAL FIELD

The present disclosure relates to a semiconductor device.

### BACKGROUND ART

PTL 1 discloses a semiconductor device as a frontside-type (front-illuminated) solid-state imaging device.

In the semiconductor device, a semiconductor chip is joined onto a semiconductor substrate with a bump electrode interposed therebetween. A lens material is formed in a region other than a region in which the bump electrode is formed on the semiconductor substrate. In the region in which the lens material is formed, photoelectric conversion elements are arranged on the semiconductor substrate. A peripheral circuit or the like that processes signals from the photoelectric conversion elements is formed in the semiconductor chip.

### CITATION LIST

### Patent Literature

PTL 1: Japanese Unexamined Patent Application Publication No. 2016-163011

### SUMMARY OF THE INVENTION

In a semiconductor device disclosed in PTL 1 described above, it tends to be difficult to reserve a packaging area of a semiconductor chip on a semiconductor substrate due to enlargement of a light reception region in which photoelectric conversion elements are arranged. For example, in a semiconductor device that constructs a solid-state imaging device, it is therefore desirable to achieve higher packaging density of a semiconductor chip.

A semiconductor device according to a first aspect of the present disclosure includes: a first semiconductor element including a pixel region in which a plurality of pixels is arranged on one surface; a second semiconductor element packaged in a region different from the pixel region on the one surface, and including a first circuit that is electrically coupled to the pixel; and a third semiconductor element packaged on the second semiconductor element on a side opposite to the first semiconductor element, and including a second circuit that is electrically coupled to the pixel.

In a semiconductor device according to a second aspect of the present disclosure, a thickness of a semiconductor substrate of the second semiconductor element is thinner than a thickness in a same direction of a semiconductor substrate of the third semiconductor element in the semiconductor device according to the first aspect.

### BRIEF DESCRIPTION OF THE DRAWINGS

FIG. 1 is a longitudinal cross-sectional configuration diagram of a main part of a semiconductor device according to a first embodiment of the present disclosure.

FIG. 2 is a planar configuration diagram of the semiconductor device illustrated in FIG. 1.

FIG. 3 is a first step cross-sectional view of a manufacturing method of the semiconductor device according to the first embodiment for each of steps.

FIG. 4 is a second step cross-sectional view.

FIG. 5 is a third step cross-sectional view.

FIG. 6 is a fourth step cross-sectional view.

FIG. 7 is a fifth step cross-sectional view.

FIG. 8 is a sixth step cross-sectional view.

FIG. 9 is a longitudinal cross-sectional configuration diagram, corresponding to FIG. 1, of a semiconductor device according to a second embodiment of the present disclosure.

FIG. 10 is a planar configuration diagram, corresponding to FIG. 2, of the semiconductor device illustrated in FIG. 9.

FIG. 11 is a planar configuration diagram, corresponding to FIG. 2, of a semiconductor device according to a third embodiment of the present disclosure.

FIG. 12 is a longitudinal cross-sectional configuration diagram, corresponding to FIG. 1, of a semiconductor device according to a fourth embodiment of the present disclosure.

FIG. 13 is a planar configuration diagram, corresponding to FIG. 2, of the semiconductor device illustrated in FIG. 12.

FIG. 14 is a planar configuration diagram, corresponding to FIG. 2, of a semiconductor device according to a fifth embodiment of the present disclosure.

FIG. 15 is a planar configuration diagram, corresponding to FIG. 2, of a semiconductor device according to a sixth embodiment of the present disclosure.

FIG. 16 is a longitudinal cross-sectional configuration diagram, corresponding to FIG. 1, of a semiconductor device according to a seventh embodiment of the present disclosure.

FIG. 17 is a longitudinal cross-sectional configuration diagram, corresponding to FIG. 1, of a semiconductor device according to an eighth embodiment of the present disclosure.

FIG. 18 is a longitudinal cross-sectional configuration diagram, corresponding to FIG. 1, of a semiconductor device according to a ninth embodiment of the present disclosure.

FIG. 19 is a system configuration diagram of a semiconductor device according to a tenth embodiment of the present disclosure.

FIG. 20 is a system configuration diagram of a semiconductor device according to an eleventh embodiment of the present disclosure.

FIG. 21 is a schematic perspective view of a semiconductor device according to a twelfth embodiment of the present disclosure.

FIG. 22 is a system configuration diagram of a semiconductor device according to a thirteenth embodiment of the present disclosure.

FIG. 23 is a schematic perspective view, corresponding to FIG. 21, of the semiconductor device illustrated in FIG. 22.

FIG. 24 is a block diagram depicting an example of schematic configuration of a vehicle control system.

FIG. 25 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that description is given in the following order.

### 1. First Embodiment

A first embodiment describes a first example in which the present technology is applied to a semiconductor device. In the first embodiment, the semiconductor device constructs a back-illuminated solid-state imaging device. In addition, the first embodiment describes a longitudinal cross-sectional configuration, a planar configuration, and a manufacturing method of the semiconductor device.

### 2. Second Embodiment

A second embodiment describes a second example in which packaging structures of semiconductor elements are changed in the semiconductor device according to the first embodiment.

### 3. Third Embodiment

A third embodiment describes a third example in which a packaging layout of semiconductor elements is changed in the semiconductor device according to the second embodiment.

### 4. Fourth Embodiment

A fourth embodiment describes a fourth example in which the packaging structures of the semiconductor elements are changed in the semiconductor device according to the second embodiment.

### 5. Fifth Embodiment

A fifth embodiment describes a fifth example in which the packaging layout of the semiconductor elements is changed in the semiconductor device according to the first embodiment.

### 6. Sixth Embodiment

A sixth embodiment describes a sixth example in which the packaging layout of the semiconductor element is changed in the semiconductor device according to the fifth embodiment.

### 7. Seventh Embodiment

A seventh embodiment describes a seventh example in which a semiconductor element is further added in the semiconductor device according to the first embodiment.

### 8. Eighth Embodiment

An eighth embodiment describes an eighth example in which the semiconductor device according to the first embodiment is applied to a front-illuminated solid-state imaging device.

### 9. Ninth Embodiment

A ninth embodiment describes a ninth example in which the packaging structures of the semiconductor elements are changed in the semiconductor device according to the first embodiment.

### 10. Tenth Embodiment

A tenth embodiment describes an optimal system configuration in the semiconductor device according to the second embodiment.

### 11. Eleventh Embodiment

An eleventh embodiment describes a first application example of the system configuration in the semiconductor device according to the tenth embodiment.

### 12. Twelfth Embodiment

A twelfth embodiment describes a second application example of the system configuration in the semiconductor device according to the tenth embodiment.

### 13. Thirteenth Embodiment

A thirteenth embodiment describes a third application example of the system configuration in the semiconductor device according to the tenth embodiment.

### 14. Example of Application to Mobile Body

The application example describes an example in which the present technology is applied to a vehicle control system that is an example of a mobile body control system.

### 15. Other Embodiments

### 1. First Embodiment

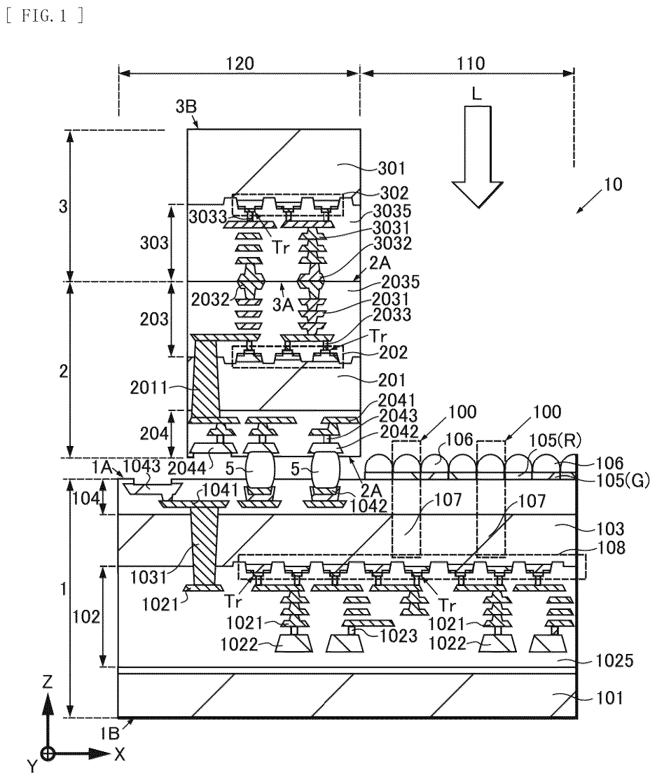

Description is given of a semiconductor device 10 according to the first embodiment of the present disclosure with reference to FIGS. 1 to 8.

Here, an arrow-X direction indicated as appropriate in the drawings indicates one planar direction of the semiconductor device 10 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### Configuration of Semiconductor Device 10

### (1) Overall Configuration of Semiconductor Device 10

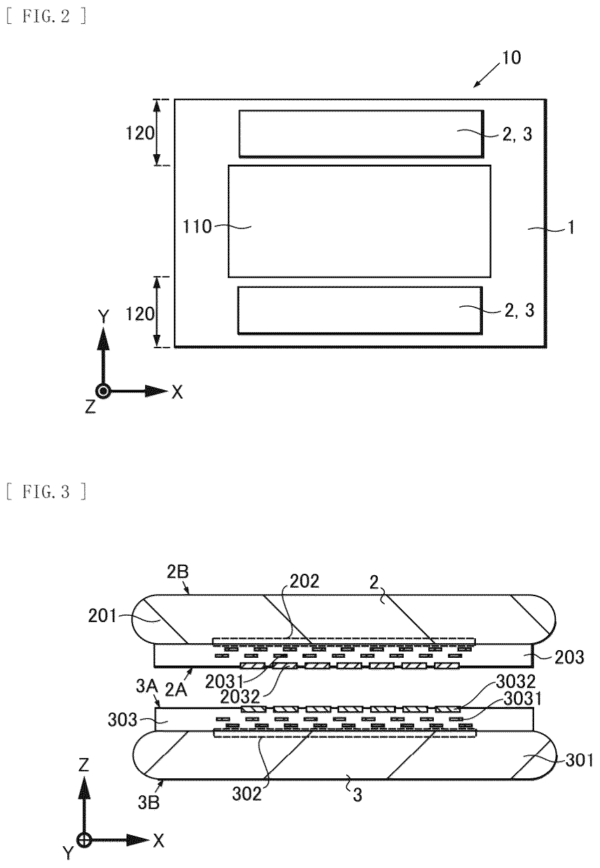

FIG. 1 illustrates an example of a longitudinal cross-sectional configuration of the semiconductor device 10 according to the first embodiment. FIG. 2 illustrates an example of a planar configuration of the semiconductor device 10 illustrated in FIG. 1.

As illustrated in FIGS. 1 and 2, the semiconductor device 10 according to the first embodiment constructs a back-illuminated solid-state imaging device. To describe this in more detail, the semiconductor device 10 is constructed as a CMOS (Complementary Metal Oxide Semiconductor) image sensor. The semiconductor device 10 includes a first semiconductor element 1, a second semiconductor element 2, and a third semiconductor element 3 as main components.

### (2) Configuration of First Semiconductor Element 1

As illustrated in FIGS. 1 and 2, the first semiconductor element I includes a pixel region 110 in which a plurality of pixels 100 is arranged on a front surface IA on a side in the arrow-Z direction. The pixels 100 are arranged, for example, in the arrow-X direction and the arrow-Y direction. Here, the front surface 1A corresponds to “one surface of a first semiconductor element” according to the present technology.

### (2-1) Configurations of Support Substrate 101 and Semiconductor Substrate 103

To describe this in detail, the first semiconductor element 1 includes a support substrate 101 and a semiconductor substrate 103.

The support substrate 101 is formed by, for example, a single-crystalline silicon (Si) substrate. A side opposite to the arrow-Z direction of the support substrate 101 is a back surface 1B, opposed to the front surface 1A, of the first semiconductor element 1.

The semiconductor substrate 103 is stacked on the support substrate 101 on the side in the arrow-Z direction. The semiconductor substrate 103 is formed by, for example, a single-crystalline Si substrate. The semiconductor substrate 103 has, for example, a thickness of greater than or equal to 2 μm and less than or equal to 13 μm.

The semiconductor substrate 103 is stacked on the support substrate 101 with an insulator, whose reference numeral is omitted, interposed therebetween. The insulator is formed by a silicon nitride (SiN) film.

As illustrated in FIG. 2, the support substrate 101 and the semiconductor substrate 103 are each formed in a rectangular shape as viewed in the arrow-Z direction (hereinafter, simply referred to as “in a plan view”), and are formed to have the same plane area (plane size). That is, the first semiconductor element 1 is formed as a semiconductor chip processed as a die (Die) by dicing a semiconductor wafer in a manufacturing process. Here, a planar shape of the first semiconductor element 1 is formed in a rectangular shape having a longer side in the arrow-X direction and a shorter side in the arrow-Y direction.

Here, “as viewed in a thickness direction of the first semiconductor element 1” according to the present technology corresponds to “in a plan view as viewed in the arrow-Z direction”.

### (2-2) Configurations of Pixel 100 and Pixel Region 110

As illustrated in FIGS. 1 and 2, the pixel region 110 is provided in a middle portion of the front surface IA of the first semiconductor element 1. Each of the pixels 100 that construct the pixel region 110 includes at least a photoelectric conversion element 107. The pixels 100 each further include an optical filter 105 and an optical lens 106.

Although a detailed structure is omitted, as illustrated in FIG. 1, the photoelectric conversion element 107 is provided in the semiconductor substrate 103. The photoelectric conversion element 107 converts incident light L incident in the arrow-Z direction into electric charge. Here, the photoelectric conversion element 107 is formed by, for example, a photodiode.

The optical filter 105 is provided on the semiconductor substrate 103 with an insulator 104 interposed therebetween on a side of the front surface 1A. The optical filter 105 includes color filters of a total of three colors different for respective pixels 100. That is, the optical filter 105 includes a red light filter (R), a green light filter (G), and a blue light filter (B) (which are not illustrated). The red light filter (R) allows light of a red light band to pass therethrough. The green light filter (G) allows light of a green light band to pass therethrough. The blue light filter (B) allows light of a blue light band to pass therethrough. The optical filter 105 is formed by, for example, a resin material including a dye.

The optical lens 106 is provided on the optical filter 105 on a side opposite to the photoelectric conversion element 107. In other words, the optical lens 106 is provided on the optical filter 105 on the side of the front surface 1A. Although not illustrated in a plan view, the optical lens 106 is formed in a circular shape for each of the pixels 100. In addition, the optical lens 106 is formed, for each of the pixels 100, in a curved shape that curves toward a light incident side to condense the incident light L in the photoelectric conversion element 107, as viewed in the arrow-Y direction (hereinafter, referred to as “in a side view”).

The optical lens 106 is formed as what is called an on-chip lens, and is integrally formed for each of the pixels 100 or across a plurality of pixels 100. The optical lens 106 is formed by, for example, a transparent resin material.

### (2-3) Configuration of Pixel Circuit 108

As illustrated in FIG. 1, a pixel circuit 108 is electrically coupled to one pixel 100 or a plurality of pixels 100 with an unillustrated transfer transistor interposed therebetween.

Although illustration of a detailed circuit configuration of the pixel circuit 108, and illustration and description of a longitudinal cross-sectional configuration of the pixel circuit 108 in a side view are omitted, the pixel circuit 108 includes a plurality of transistors Tr. For example, the pixel circuit 108 includes the transistors Tr to be used as a reset transistor, an amplification transistor, a select transistor, and the like.

The transistors Tr that include the transfer transistor and construct the pixel circuit 108 are each formed by, for example, an n-channel electrically conductive type insulated gate field effect transistor (IGFET). The pixel circuit 108 is provided in a main surface portion of the semiconductor substrate 103 on a side of the support substrate 101.

### (2-4) Configuration of Wiring Layer 102

A wiring layer 102 is provided on the semiconductor substrate 103 on the side of the support substrate 101. In other words, the wiring layer 102 is provided just between the semiconductor substrate 103 and the support substrate 101.

For example, a wiring 1021 with a plurality of layers and a wiring 1022 are formed in the wiring layer 102. The wiring 1021 and the wiring 1022 couple the plurality of transistors Tr together. The plurality of transistors Tr constructs the pixel circuit 108. For example, a metal wiring material such as copper (Cu) is used for the wiring 1021. For example, a metal wiring material such as an aluminum (Al)—Cu alloy is used for the wiring 1022. In addition, a plug wiring 1023 is used to couple the wiring 1021 and the wiring 1022. For example, a metal wiring material such as tungsten (W) or an Al—Cu alloy is used for the plug wiring 1023.

Although illustrated in a simplified manner, an insulator 1025 is formed, for example, between the wirings 1021 with the plurality of layers and between the wiring 1021 and the wiring 1022. The insulator 1025 is formed by, for example, a silicon oxide (SiO₂) film.

### (2-5) Configuration of Packaging Region 120

As illustrated in FIGS. 1 and 2, a packaging region 120 is provided in a peripheral portion of the front surface 1A of the first semiconductor element 1. The peripheral portion surrounds the pixel region 110 provided in the middle portion of the front surface 1A of the first semiconductor element 1. The second semiconductor element 2 and the third semiconductor element 3 are packaged in the packaging region 120.

Detailed description is given of this point. A plurality of terminals 1042 is provided in the packaging region 120. The terminals 1042 are provided in a front surface portion on the side in the arrow-Z direction of the insulator 104. The terminals 1042 are configured as external terminals that mechanically join the second semiconductor element 2 for packaging, and electrically couple the pixels 100 of the first semiconductor element 1 to a first circuit 202 of the second semiconductor element 2. In addition, the terminals 1042 are further configured as external terminals that electrically couple the pixels 100 to a second circuit 302 of the third semiconductor element 3.

The terminals 1042 are each electrically coupled to the wiring 1021 of the wiring layer 102 through a wiring 1041 and a through wiring 1031. The wiring 1041 is provided closer to the semiconductor substrate 103 than the terminals 1042. The through wiring 1031 penetrates the semiconductor substrate 103 in the thickness direction. For example, a metal wiring material such as Cu is used for the terminals 1042, the wiring 1041, and the through wiring 1031.

In addition, although not described in detail, the insulator 104 is provided between the terminals 1042 and the wiring 1041. The insulator 104 is used as an interlayer insulating film in the packaging region 120. The insulator 104 is formed by, for example, a SiO₂ film.

Here, the terminal 1042 corresponds to a “first terminal” according to the present technology.

In actuality, the pixel 100 is electrically coupled to the first circuit 202 of the second semiconductor element 2 through the pixel circuit 108. The term “electrically coupling a first circuit to a pixel” is used to mean both “indirectly electrically coupling the pixel 100 to the first circuit 202 with the pixel circuit 108 interposed therebetween“ and ”directly electrically coupling the pixel 100 to the first circuit 202”.

In addition, as illustrated in FIG. 1, a terminal 1043 for inspection is provided in a region around the pixel region 110 and along an outer edge of the first semiconductor element 1. The terminal 1043 is used for electric characteristic inspection to be executed during a manufacturing step of the semiconductor device 10 or after completion of the manufacturing step, for example. In the inspection, an inspection probe comes in contact with the terminal 1043.

The terminal 1043 is formed by, for example, a metal wiring material similar to that of the wiring 1022 of the wiring layer 102.

### (3) Configuration of Second Semiconductor Element 2

As illustrated in FIGS. 1 and 2, the second semiconductor element 2 is packaged in the packaging region 120 on the side of the front surface 1A of the first semiconductor element 1. That is, the second semiconductor element 2 is packaged in a region different from the pixel region 110 of the first semiconductor element 1.

The second semiconductor element 2 includes a semiconductor substrate 201 and the first circuit 202.

### (3-1) Configuration of Semiconductor Substrate 201

The semiconductor substrate 201 is formed by, for example, a single-crystalline Si substrate, as with the semiconductor substrate 103 of the first semiconductor element 1. Here, the semiconductor substrate 201 is formed to have a thickness thinner than the thickness of the semiconductor substrate 103 of the first semiconductor element I and thinner than a semiconductor substrate 301 of the third semiconductor element 3 to be described later. The semiconductor substrate 201 has, for example, a thickness of 10 μm or less. Here, the thickness of the semiconductor substrate 201 is set to greater than or equal to 1 μm and less than or equal to 10 μm.

### (3-2) Configuration of First Circuit 202

As illustrated in FIG. 1, the first circuit 202 is provided on the side in the arrow-Z direction (on a side of the third semiconductor element 3) and on a side of a front surface 2A of the semiconductor substrate 201. The first circuit 202 is indirectly electrically coupled to the pixel 100 of the pixel region 110 with the pixel circuit 108 interposed therebetween.

The first circuit 202 includes one or a plurality of logic circuits selected from among, for example, a vertical drive circuit, column signal processing circuits, a horizontal drive circuit, an output circuit, and a control circuit that construct a peripheral circuit of the back-illuminated solid-state imaging device. The first circuit 202 is constructed to include the transistors Tr, a resistor, a capacitor, and the like, as with the pixel circuit 108. It is to be noted that in the second circuit 302 provided in the third semiconductor element 3 to be described later a logic circuit similar to that of the first circuit 202 is divided, or the second circuit 302 includes another logic circuit that is not selected in the first circuit 202.

Although specific description of circuit configuration of the logic circuits is omitted, the control circuit described above receives an input clock and data adapted to command an operation mode and the like, and also outputs data such as internal information concerning a solid-state imaging device. That is, the control circuit generates, on the basis of a vertical synchronization signal, a horizontal synchronization signal, and a master clock, a control signal or a clock signal adapted to serve as reference for operations of the vertical drive circuit, the column signal processing circuits, the horizontal drive circuit, and the like. Moreover, these signals are inputted to the vertical drive circuit, the column signal processing circuits, the horizontal drive circuit, and the like.

The vertical drive circuit includes, for example, a shift register. The vertical drive circuit selects a pixel drive wiring, and supplies the selected pixel drive wiring with a pulse adapted to drive the pixels 100. The pixels 100 are driven on a row-by-row basis. That is, the vertical drive circuit selectively scans each of the pixels 100 of the pixel region 110 sequentially in a vertical direction on a row-by-row basis. Signal charge generated depending on an amount of the incident light L received by the photoelectric conversion element 107 of each of the pixels 100 is supplied as a pixel signal to the column signal processing circuit through a vertical signal line.

The column signal processing circuit is provided, for example, for each of columns of the pixels 100. The column signal processing circuit performs, for each of pixel columns, signal processing such as noise removal on signals outputted from one row of the pixels 100. That is, the column signal processing circuit performs signal processing such as CDS (Correlated Double Sampling), signal amplification, or AD (Analog Digital) conversion. The CDS is adapted to remove fixed pattern noise inherent in the pixels 100. An unillustrated horizontal selection switch is coupled to an output stage of the column signal processing circuits between the column signal processing circuit and a horizontal signal line.

The horizontal drive circuit includes, for example, a shift register. The horizontal drive circuit selects in sequence each of the column signal processing circuits by sequentially outputting horizontal scan pulses, and outputs, to the horizontal signal line, the pixel signals from each of the column signal processing circuits.

The output circuit performs signal processing on the signals sequentially supplied from each of the column signal processing circuits through the horizontal signal line, and outputs the resultant signals. For example, the output circuit only performs buffering in some cases, and performs black level adjustment, column variation correction, and various types of digital signal processing in other cases.

In addition, the logic circuit includes an unillustrated input/output terminal. The input/output terminal exchanges signals between the back-illuminated solid-state imaging device (the semiconductor device 10) and the outside. Here, although not illustrated, the input/output terminal is formed by the same configuration as that of the terminal 1043, and is provided on the side of the front surface IA of the first semiconductor element 1.

### (3-3) Configurations of Wiring Layer 203 and Wiring Layer 204

A wiring layer 203 is provided on the side of the front surface 2A of the semiconductor substrate 201. For example, a wiring 2031 with a plurality of layers and a terminal 2032 are formed in the wiring layer 203. The wiring 2031 and the terminal 2032 couple, for example, logic circuits together, and a logic circuit and the pixel circuit 108 together. For example, a metal wiring material such as Cu is used for the wiring 2031 and the terminal 2032. In addition, a plug wiring 2033 is formed on the wiring 2031. The plug wiring 2033 is electrically coupled to the transistor Tr of the first circuit 202. For example, a metal wiring material such as W is used for the plug wiring 2033.

Although illustrated in a simplified manner, an insulator 2035 is formed, for example, between the wirings 2031 with the plurality of layers and between the wiring 2031 and the wiring 2032. The insulator 2035 is formed by, for example, a SiO₂ film.

A front surface of the terminal 2032 is exposed from the insulator 2035. A terminal 3032 of the third semiconductor element 3 to be described later is joined to the terminal 2032. That is, the terminal 2032 causes the third semiconductor element 3 to be packaged, and is electrically coupled to the terminal 3032.

Here, the terminal 2032 corresponds to a “third terminal” according to the present technology. In addition, the terminal 3032 corresponds to a “fourth terminal” according to the present technology.

Meanwhile, a wiring layer 204 is provided on a side of a back surface 2B of the semiconductor substrate 201. For example, a wiring 2041 with a plurality of layers and a terminal 2042 are formed in the wiring layer 204. The wiring 2041 and the terminal 2042 couple, for example, logic circuits together, and a logic circuit and the pixel circuit 108 together. For example, a metal wiring material such as Cu is used for the wiring 2041. In addition, for example, a metal wiring material such as an Al—Cu alloy is used for the terminal 2042. In addition, the terminal 2042 is electrically coupled to the wiring 2041 with a plug wiring 2043 interposed therebetween. For example, a metal wiring material such as W is used for the plug wiring 2043.

Here, the terminal 2042 corresponds to a “second terminal” according to the present technology.

Furthermore, a terminal 2044 for inspection is provided in the wiring layer 204 of the second semiconductor element 2. As with the terminal 1043, the terminal 2044 is used for electric characteristic inspection to be executed during a manufacturing step of the semiconductor device 10 or after completion of the manufacturing step, for example.

The terminal 2044 is formed by, for example, a metal wiring material similar to that of the terminal 2042 of the wiring layer 204.

Although illustrated in a simplified manner, an insulator 2045 is formed, for example, between the wirings 2041 with the plurality of layers and between the wiring 2041 and the terminal 2042. The insulator 2045 is formed by, for example, a SiO₂ film.

The wiring 2401 of the wiring layer 204 is electrically coupled to the wiring 2031 of the wiring layer 203 through a through wiring 2011. The through wiring 2011 is provided to penetrate the semiconductor substrate 201 of the second semiconductor element 2 in the thickness direction. The through wiring 2011 is formed by, for example, a metal wiring material similar to that of the through wiring 1031.

In the second semiconductor element 2, the semiconductor substrate 201 is formed to be thin, which makes it possible to easily provide the through wiring 2011.

Here, the through wiring 2011 corresponds to a “first through wiring” according to the present technology.

### (3-4) Packaging Method of Second Semiconductor Element 2

As illustrated in FIG. 1, the second semiconductor element 2 is packaged in the packaging region 120 on the side of the front surface 2A of the first semiconductor element 1 in a face-up manner in which the first circuit 202 is directed in the same arrow-Z direction.

To describe this in detail, the terminal 2042 of the wiring layer 204 of the second semiconductor element 2 is electrically coupled to the terminal 1042 provided in the packaging region 120 of the first semiconductor element 1, and the second semiconductor element 2 is packaged on the first semiconductor element 1. A bump electrode 5 is used for this packaging. Here, a microbump electrode is used for the bump electrode 5.

For example, Sn-based solder such as a tin (Sn)-silver (Ag) alloy is used for the bump electrode 5.

As illustrated in FIG. 2, a planar shape of the second semiconductor element 2 is formed in a rectangular shape in a plan view. A plane area (a plane size) of the second semiconductor element 2 is smaller than a plane area (a plane size) of the first semiconductor element 1. Moreover, the second semiconductor element 2 is provided within the front surface 1A of the first semiconductor element 1. In other words, the second semiconductor element 2 is packaged in the peripheral portion around the pixel region 110 within the front surface 1A of the first semiconductor element 1.

In the present technology, it is sufficient if the second semiconductor element 2 is packaged along at least one side of the first semiconductor element 1 formed in a rectangular shape. In the first embodiment, a total of two second semiconductor elements 2 are packaged along respective two sides opposed to each other in the arrow-Y direction of the first semiconductor element 1.

### (4) Configuration of Third Semiconductor Element 3

As illustrated in FIGS. 1 and 2, the third semiconductor element 3 is packaged on the side of the front surface 2A of the second semiconductor element 2. That is, as with the second semiconductor element 2, the third semiconductor element 3 is packaged in the packaging region 120 different from the pixel region 110 of the first semiconductor element 1.

The third semiconductor element 3 includes the semiconductor substrate 301 and the second circuit 302.

### (4-1) Configuration of Semiconductor Substrate 301

The semiconductor substrate 301 is formed by, for example, a single-crystalline Si substrate, as with the semiconductor substrate 103 of the first semiconductor element 1. Here, the semiconductor substrate 301 is formed to have a thickness thinner than the thickness of the semiconductor substrate 103 of the first semiconductor element 1, and thicker than the semiconductor substrate 201 of the second semiconductor element 2 as described above. The semiconductor substrate 301 has, for example, a thickness of greater than or equal to 100 μm and less than or equal to 800 μm. Here, the thickness of the semiconductor substrate 301 is set to greater than or equal to 100 μm and less than or equal to 400 μm, for example.

### (4-2) Configuration of Second Circuit 302

As illustrated in FIG. 1, the second circuit 302 is provided on a side opposite to the arrow-Z direction (on a side of the second semiconductor element 2) and on a side of a front surface 3A of the semiconductor substrate 301. The second circuit 302 is indirectly electrically coupled to the pixel 100 of the pixel region 110 with the pixel circuit 108 interposed therebetween or with the pixel circuit 108 and the first circuit 202 interposed therebetween.

As described above, the second circuit 302 includes a logic circuit. As with the pixel circuit 108, the second circuit 302 is constructed to include the transistors Tr, a resistor, a capacitor, and the like.

### (4-3) Configuration of Wiring Layer 303

A wiring layer 303 is provided on the side of the front surface 3A of the semiconductor substrate 301. For example, a wiring 3031 with a plurality of layers and the terminal 3032 are formed in the wiring layer 303. The wiring 3031 and the terminal 3032 couple, for example, logic circuits together. For example, a metal wiring material such as Cu is used for the wiring 3031 and the terminal 3032. In addition, a plug wiring 3033 is formed on the wiring 3031. The plug wiring 3033 is electrically coupled to the transistor Tr of the second circuit 302. For example, a metal wiring material such as W is used for the plug wiring 3033.

It is to be noted that, in the first embodiment, no wiring layer is provided on the back surface 2B of the semiconductor substrate 301.

Although illustrated in a simplified manner, an insulator 3035 is formed, for example, between the wirings 3031 with the plurality of layers and between the wiring 3031 and the terminal 3032. The insulator 3035 is formed by, for example, a SiO₂ film.

A front surface of the terminal 3032 is exposed from the insulator 3035. The terminal 2032 of the second semiconductor element 2 is joined to the terminal 3032. That is, the terminal 3032 causes the third semiconductor element 3 to be packaged on the second semiconductor element 2, and is electrically coupled to the terminal 2032.

### (4-4) Packaging Method of Third Semiconductor Element 3

As illustrated in FIG. 1, the third semiconductor element 3 is packaged in a face-down manner that is in a state in which the front surface 3A on which the second circuit 302 is provided is opposed to the front surface 2A, on which the first circuit 202 is provided, of the second semiconductor element 2.

To describe this in detail, the terminal 3032 that is electrically coupled to the second circuit 302 of the third semiconductor element 3 is joined to the terminal 2032 that is electrically coupled to the first circuit 202 of the second semiconductor element 2. Here, for example, Cu is used for each of the terminal 2032 and the terminal 3032; therefore, Cu—Cu bonding is made. That is, the terminal 2032 and the terminal 3032 are mechanically and electrically coupled to each other.

As illustrated in FIG. 2, a planar shape of the third semiconductor element 3 is formed in the same rectangular shape as the planar shape of the second semiconductor element 2 in a plan view. Furthermore, a plane area (a plane size) of the third semiconductor element 3 is the same as the plane area (the plane size) of the second semiconductor element 2. Moreover, the third semiconductor element 3 is packaged at the same packaging position as a packaging position of the second semiconductor element 2. That is, in the first embodiment, the third semiconductor element 3 is packaged on each of the two second semiconductor elements 2.

### Manufacturing Method of Semiconductor Device 10

Next, description is given of a manufacturing method of the semiconductor device 10 according to the first embodiment, specifically, a manufacturing method of the second semiconductor element 2 and the third semiconductor element 3 packaged on the first semiconductor element 1. FIGS. 3 to 8 illustrate an example of a step cross-section for describing the manufacturing method of the semiconductor device 10 for each of steps.

First, as illustrated in FIG. 3, the semiconductor substrate 301 of the third semiconductor element 3 and the semiconductor substrate 201 of the second semiconductor element 2 are formed. Each of the semiconductor substrate 301 and the semiconductor substrate 201 is in a semiconductor wafer state.

The second circuit 302 is formed on the side of the front surface 3A of the semiconductor substrate 301, and the wiring layer 303 is further formed. The terminal 3032 is formed in an uppermost layer of the wiring layer 303.

Meanwhile, the first circuit 202 is formed on the side of the front surface 2A of the semiconductor substrate 201, and the wiring layer 203 is further formed. The terminal 2032 is formed in an uppermost layer of the wiring layer 203.

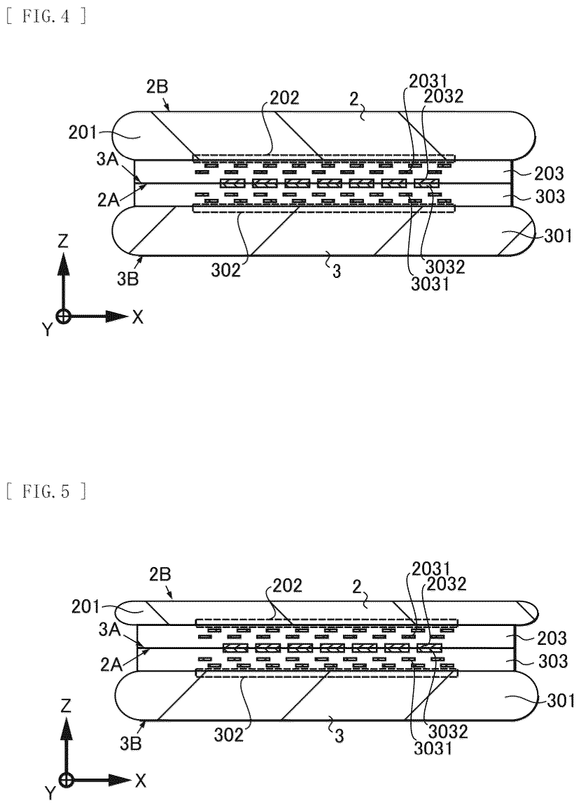

As illustrated in FIG. 4, the front surface 3A of the semiconductor substrate 301 and the front surface 2A of the semiconductor substrate 201 are opposed to each other, and the terminal 2032 is joined to the terminal 3032. That is, the second semiconductor element 2 is packaged on the third semiconductor element 3.

As illustrated in FIG. 5, the back surface 2B of the semiconductor substrate 201 of the second semiconductor element 2 is polished to thin the semiconductor substrate 201.

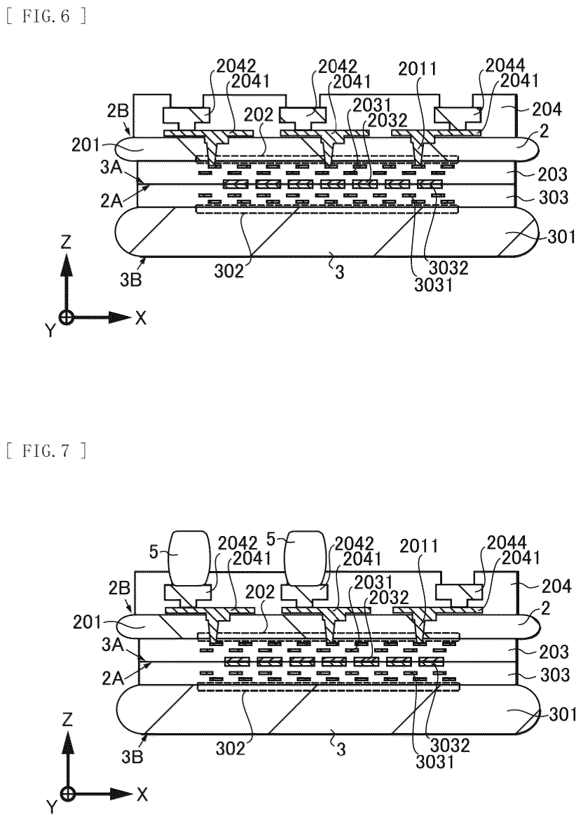

As illustrated in FIG. 6, the wiring layer 204 is formed on the side of the back surface 2B of the semiconductor substrate 201. The terminal 2042 and the terminal 2044 are formed in an uppermost layer of the wiring layer 204. As described above, the terminal 2042 is formed as a terminal that causes the second semiconductor element 2 to be packaged on the first semiconductor element 1 (refer to FIG. 1). Meanwhile, the terminal 2044 is formed as a terminal for inspection.

As illustrated in FIG. 7, the bump electrode 5 is formed on the terminal 2042. Meanwhile, the bump electrode 5 is not formed on the terminal 2044.

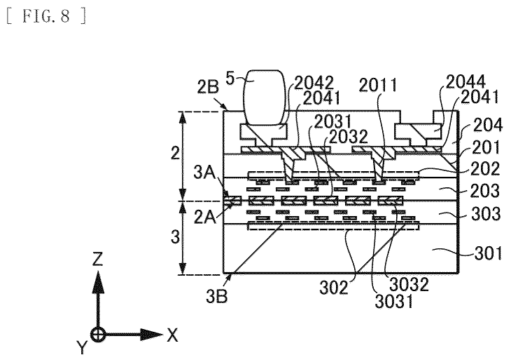

As illustrated in FIG. 8, the semiconductor substrate 301 and the semiconductor substrate 201 are diced (into semiconductor chips) by dicing processing. Accordingly, the third semiconductor element 3 is formed from the semiconductor substrate 301 including the wiring layer 303, and the second semiconductor element 2 is formed from the semiconductor substrate 201 including the wiring layer 203 and the wiring layer 204. In this step, the third semiconductor element 3 is in a state of being packaged on the second semiconductor element 2.

Thereafter, as illustrated in FIGS. 1 and 2 described above, the second semiconductor element 2 on which the third semiconductor element 3 is packaged is packaged in the packaging region 120 of the first semiconductor element 1, thereby completing the manufacturing method of the semiconductor device 10 according to the first embodiment, and completing the semiconductor device 10.

### Workings and Effects

As described above, as illustrated in FIGS. 1 and 2, the semiconductor device 10 according to the first embodiment includes the first semiconductor element 1, the second semiconductor element 2, and the third semiconductor element 3.

The first semiconductor element I includes the pixel region 110 on the front surface 1A. In the pixel region 110, the plurality of pixels 100 is arranged The second semiconductor element 2 is packaged in a region different from the pixel region 110 of the front surface 1A, and includes the first circuit 202 that is electrically coupled to the pixel 100. Here, the region different from the pixel region 110 is the packaging region 120. The third semiconductor element 3 is packaged on the second semiconductor element 2 on a side opposite to the first semiconductor element 1, and includes the second circuit 302 that is electrically coupled to the pixel 100.

In the semiconductor device 10 having such a configuration, the second semiconductor element 2 and the third semiconductor element 3 are stacked in the region different from the pixel region 110, which makes it possible to improve packaging density in the thickness direction of the first semiconductor element 1. Accordingly, it is possible to improve packaging density of the peripheral circuit including the first circuit 202 and the second circuit 302 while enlarging the pixel region 110.

In addition, in the semiconductor device 10, as illustrated in FIG. 2, the plane area of each of the second semiconductor element 2 and the third semiconductor element 3 is smaller than the plane area of the first semiconductor element 1, as viewed in the thickness direction of the first semiconductor element 1 (in a plan view).

Accordingly, it is possible to further enlarge the pixel region 110 of the first semiconductor element 1.

In addition, in the semiconductor device 10, as illustrated in FIG. 2, each of the second semiconductor element 2 and the third semiconductor element 3 is provided within the front surface LA of the first semiconductor element 1, as viewed in the thickness direction of the first semiconductor element (in a plan view).

Accordingly, it is possible to improve packaging density while enlarging the pixel region 110 within the front surface 1A of the first semiconductor element 1.

In addition, in the semiconductor device 10, as illustrated in FIG. 1, the semiconductor substrate 201 of the second semiconductor element 2 has a thickness thinner than the thickness of the semiconductor substrate 301 in the same direction of the third semiconductor element 3. Moreover, in the semiconductor device 10, the second semiconductor element 2 includes the through wiring (a first through wiring) 2011 that penetrates in the thickness direction and electrically couples the pixel 100 and the first circuit 202 to each other. To describe this in detail, the through wiring 2011 is formed to penetrate the semiconductor substrate 201 of the second semiconductor element 2 in the thickness direction.

In the semiconductor device 10 having such a configuration, the semiconductor substrate 201 of the second semiconductor element 2 is formed to be thin, which makes it possible to easily process the semiconductor substrate 201. In the first embodiment, it is possible to easily form the through wiring 2011 that penetrates the semiconductor substrate 201. Accordingly, in the second semiconductor element 2, the wiring layer 203 on the side of the front surface 2A of the semiconductor substrate 201 and the wiring layer 204 on the side of the back surface 2B are electrically coupled to each other through the through wiring 2011. That is, it is possible to package each of the second semiconductor element 2 and the third semiconductor element 3 on the first semiconductor element 1 in a stacked state, which makes it possible to improve packaging density in the packaging region 120 while enlarging the pixel region 110.

In addition, as illustrated in FIG. 1, the semiconductor device 10 includes the terminal (a first terminal) 1042 on the side of the front surface IA in the first semiconductor element 1, and includes the terminal (a second terminal) 2042 on the side of the first semiconductor element 1 in the second semiconductor element 2. The terminal 1042 is electrically coupled to the pixel 100. The terminal 2042 is electrically coupled to the first circuit 202 or the second circuit 302. Moreover, the terminal 2042 is electrically coupled to the terminal 1042 with the bump electrode 5 interposed therebetween.

In the semiconductor device 10 having such a configuration, the second semiconductor element 2 is packaged on the first semiconductor element 1 with use of the bump electrode 5, which makes it possible to reduce an area occupied by the packaging region 120, as compared with a case where a bonding wire method is used for packaging. Accordingly, it is possible to improve packaging density in the packaging region 120 while enlarging the pixel region 110.

In addition, as illustrated in FIG. 1, the semiconductor device 10 includes the terminal (a third terminal) 2032 on the side of the third semiconductor element 3 in the second semiconductor element 2. The terminal 2032 is electrically coupled to the first circuit 202. The semiconductor device 10 further includes the terminal (a fourth terminal) 3032 on the side of the second semiconductor element 2 in the third semiconductor element 3. The terminal 3032 is electrically coupled to the second circuit 302. Moreover, the terminal 3032 is opposed to and joined to the terminal 2032, and the terminal 2032 and the terminal 3032 are electrically coupled to each other.

In the semiconductor device 10 having such a configuration, it is possible to package the third semiconductor element 3 within the front surface 2A of the second semiconductor element 2, which makes it possible to reduce an occupied area for packaging. Accordingly, it is possible to improve packaging density in the packaging region 120 while enlarging the pixel region 110.

In addition, in the semiconductor device 10, as illustrated in FIG. 1, the first semiconductor element 1 constructs a back-illuminated solid-state imaging device.

In the semiconductor device 10 having such a configuration, in the pixel 100 of the pixel region 110, the incident light L is efficiently taken in the photoelectric conversion element 107, which makes it possible to improve a sensitivity characteristic.

In addition, in the semiconductor device 10, as illustrated in FIGS. 1 and 2, the first circuit 202 of the second semiconductor element 2 and the second circuit 302 of the third semiconductor element 3 are logic circuits.

Accordingly, it is possible to improve packaging density of the peripheral circuit in the packaging region 120 while enlarging the pixel region 110.

Furthermore, in the semiconductor device 10, as illustrated in FIG. 2, the first semiconductor element 1 is formed in a rectangular shape, as viewed in the thickness direction (in a plan view). Moreover, the pixel region 110 is provided in the middle portion of the front surface 1A of the first semiconductor element 1, and the second semiconductor element 2 and the third semiconductor element 3 are packaged in the peripheral portion as the packaging region 120 along at least one side of the rectangular shape.

In the semiconductor device 10 having such a configuration, it is possible to improve packaging density of the peripheral circuit in the packaging region 120 while enlarging the pixel region 110.

### 2. Second Embodiment

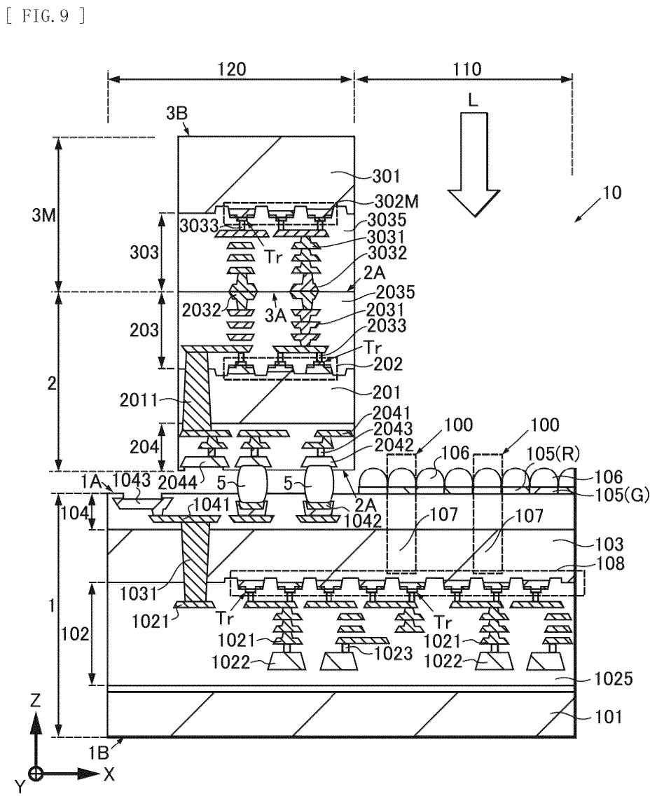

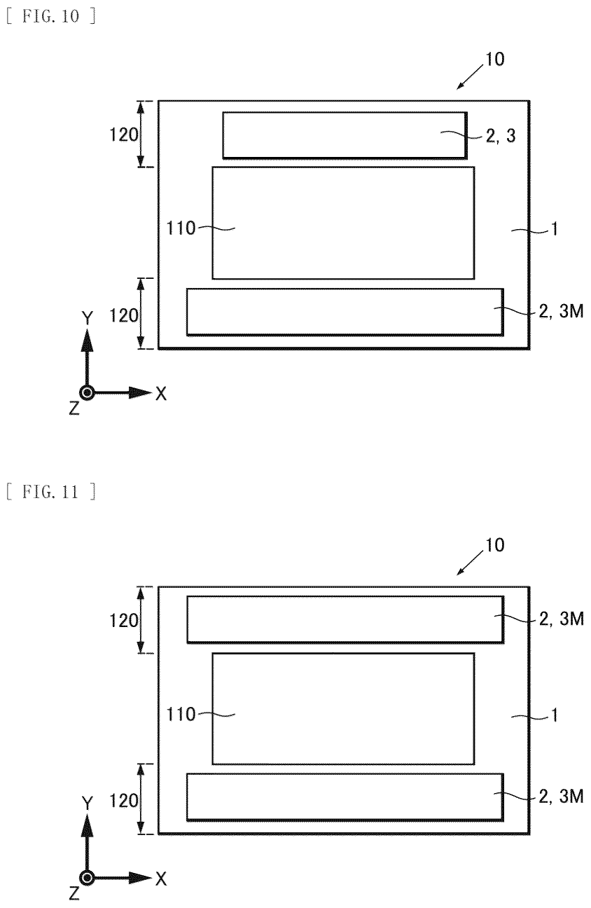

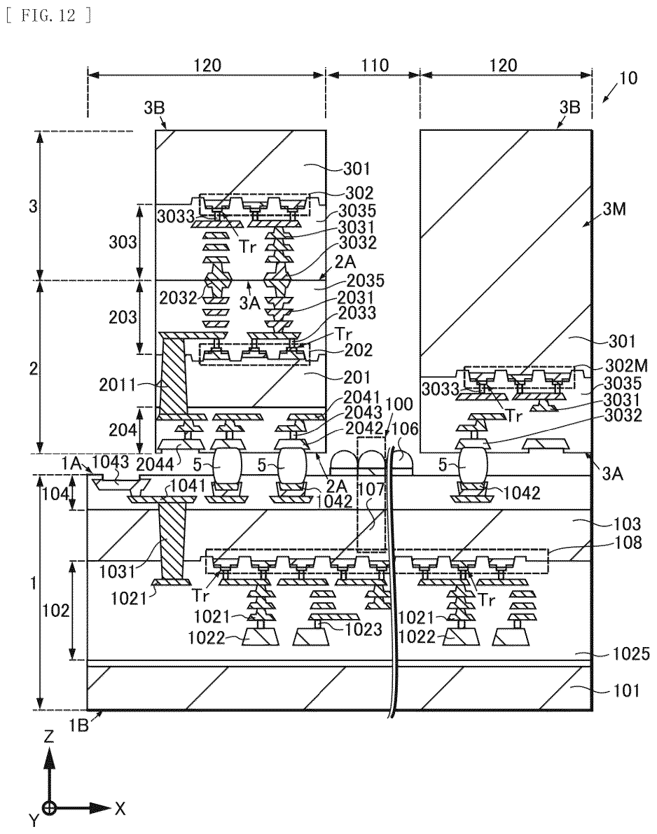

Description is given of the semiconductor device 10 according to the second embodiment of the present disclosure with reference to FIGS. 9 and 10.

It is to be noted that, in the second embodiment and the subsequent embodiments, components the same or substantially the same as the components of the semiconductor device 10 according to the first embodiment are denoted by the same reference numerals, and redundant descriptions are omitted.

### Configuration of Semiconductor Device 10

FIG. 9 illustrates an example of a longitudinal cross-sectional configuration of the semiconductor device 10 according to the second embodiment. FIG. 10 illustrates an example of a planar configuration of the semiconductor device 10 illustrated in FIG. 9.

As illustrated in FIGS. 9 and 10, the semiconductor device 10 according to the second embodiment includes a third semiconductor element 3M including a second circuit 302M in the semiconductor device 10 according to the first embodiment.

Detailed description is given of this point. As illustrated in FIGS. 9 and 10, the second semiconductor element 2 is packaged in the packaging region 120 along one side on a side in the arrow-Y direction of the first semiconductor element 1, and the third semiconductor element 3 is packaged on this second semiconductor element 2 (refer to FIGS. 1 and 2). The first circuit 202 of the second semiconductor element 2 and the second circuit 302 of the third semiconductor element 3 each construct a logic circuit, as with the first embodiment.

Meanwhile, the second semiconductor element 2 is packaged in the packaging region 120 along another side on a side opposite to the arrow-Y direction of the first semiconductor element 1, and the third semiconductor element 3M is packaged on this second semiconductor element 2. The first circuit 202 of the second semiconductor element 2 constructs a logic circuit, as with the first embodiment. The third semiconductor element 3M includes the second circuit 302M, and the second circuit 302M constructs a memory circuit. For example, the second circuit 302M is a volatile memory circuit or a nonvolatile memory circuit that accumulates signals obtained in the pixel region 110. Specifically, the second circuit 302M is a shift register that constructs a vertical drive circuit, a horizontal drive circuit, or the like.

As with the third semiconductor element 3 of the semiconductor device 10 according to the first embodiment, the third semiconductor element 3M includes the semiconductor substrate 301 and the wiring layer 303. The terminal 3032 is provided in the wiring layer 303.

The third semiconductor element 3M is packaged on the second semiconductor element 2 in a face-down manner by joining the terminal 3032 to the terminal 2032 of the second semiconductor element 2.

Components other than the above-described components are the same or substantially the same as the components of the semiconductor device 10 according to the first embodiment described above.

### Workings and Effects

In the semiconductor device 10 according to the second embodiment, it is possible to obtain workings and effects similar to the workings and effects obtained by the semiconductor device 10 according to the first embodiment.

Furthermore, the semiconductor device 10 includes the third semiconductor element 3M including the second circuit 302M. In the semiconductor device 10 having such a configuration, the second circuit 302M is a memory circuit, which allows a system configuration of the back-illuminated solid-state imaging device to have a signal accumulation function.

### 3. Third Embodiment

Description is given of the semiconductor device 10 according to the third embodiment of the present disclosure with reference to FIG. 11.

### Configuration of Semiconductor Device 10

FIG. 11 illustrates an example of a planar configuration of the semiconductor device 10 according to the third embodiment.

As illustrated in FIG. 11, as with the semiconductor device 10 according to the second embodiment, the semiconductor device 10 according to the third embodiment includes the third semiconductor element 3M including the second circuit 302M. To describe this in detail, the second semiconductor element 2 is packaged in the packaging region 120 along one side on the side in the arrow-Y direction of the first semiconductor element 1, and the third semiconductor element 3M is packaged on this second semiconductor element 2. The first circuit 202 of the second semiconductor element 2 constructs a logic circuit. The second circuit 302M of the third semiconductor element 3M constructs a memory circuit.

Likewise, the second semiconductor element 2 is packaged in the packaging region 120 along another side on the side opposite to the arrow-Y direction of the first semiconductor element 1, and the third semiconductor element 3M is packaged on this second semiconductor element 2. The first circuit 202 of the second semiconductor element 2 constructs a logic circuit. The second circuit 302M of the third semiconductor element 3M constructs a memory circuit.

That is, in the third embodiment, the third semiconductor element 3 is replaced by the third semiconductor element 3M.

Components other than the above-described components are the same or substantially the same as the components of the semiconductor device 10 according to the second embodiment described above.

### Workings and Effects

In the semiconductor device 10 according to the third embodiment, it is possible to obtain workings and effects similar to the workings and effects obtained by the semiconductor device 10 according to the second embodiment.

### 4. Fourth Embodiment

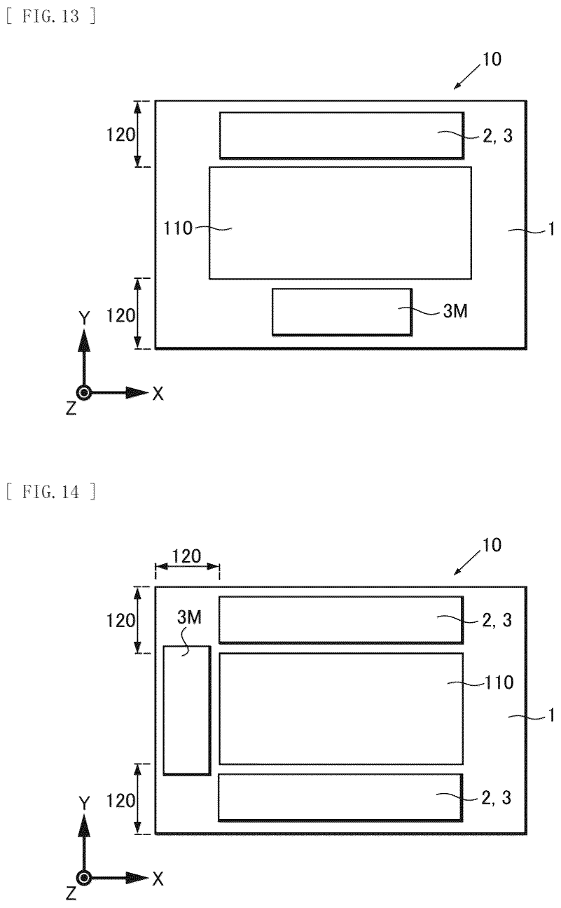

Description is given of the semiconductor device 10 according to the fourth embodiment of the present disclosure with reference to FIGS. 12 and 13.

### Configuration of Semiconductor Device 10

FIG. 12 illustrates an example of a longitudinal cross-sectional configuration of the semiconductor device 10 according to the fourth embodiment. FIG. 13 illustrates an example of a planar configuration of the semiconductor device 10 illustrated in FIG. 12.

As illustrated in FIGS. 12 and 13, the semiconductor device 10 according to the fourth embodiment has a configuration in which the semiconductor device 10 according to the first embodiment and the semiconductor device 10 according to the second embodiment or the third embodiment are combined.

Detailed description is given of this point. As illustrated in FIGS. 12 and 13, the second semiconductor element 2 is packaged in the packaging region 120 along one side on the side in the arrow-Y direction of the first semiconductor element 1, and the third semiconductor element 3 is packaged on this second semiconductor element 2. The first circuit 202 of the second semiconductor element 2 and the second circuit 302 of the third semiconductor element 3 each construct a logic circuit, as with the first embodiment.

Meanwhile, the third semiconductor element 3M is packaged alone directly in the packaging region 120 along another side on the side opposite to the arrow-Y direction of the first semiconductor element 1. The third semiconductor element 3M includes the second circuit 302M, and the second circuit 302M constructs a memory circuit.

In the third semiconductor element 3M, the terminal 3032 is mechanically and electrically coupled to the terminal 1042 in the packaging region 120 of the first semiconductor element 1 with the bump electrode 5 interposed therebetween. The third semiconductor element 3M is packaged in a face-down manner.

Here, the third semiconductor element 3M corresponds to a “fifth semiconductor element” according to the present technology. In addition, the second circuit 302M corresponds to a “fourth circuit” according to the present technology.

Components other than the above-described components are the same or substantially the same as the components of the semiconductor device 10 according to any of the first to third embodiments described above.

### Workings and Effects

In the semiconductor device 10 according to the fourth embodiment, it is possible to obtain workings and effects similar to the workings and effects obtained by the semiconductor device 10 according to the second embodiment or the third embodiment.

### 5. Fifth Embodiment

Description is given of the semiconductor device 10 according to the fifth embodiment of the present disclosure with reference to FIG. 14.

### Configuration of Semiconductor Device 10

FIG. 14 illustrates an example of a planar configuration of the semiconductor device 10 according to the fifth embodiment.

As illustrated in FIG. 14, the semiconductor device 10 according to the fifth embodiment has a configuration in which the semiconductor device 10 according to the first embodiment and the semiconductor device 10 according to the fourth embodiment are combined.

Detailed description is given of this point. As illustrated in FIG. 14, the second semiconductor element 2 is packaged in the packaging region 120 along one side on the side in the arrow-Y direction of the first semiconductor element 1, and the third semiconductor element 3 is packaged on this second semiconductor element 2. The first circuit 202 of the second semiconductor element 2 and the second circuit 302 of the third semiconductor element 3 each construct a logic circuit, as with the first embodiment.

Meanwhile, the second semiconductor element 2 is packaged in the packaging region 120 along another side on the side opposite to the arrow-Y direction of the first semiconductor element 1, and the third semiconductor element 3 is packaged on this second semiconductor element 2. The first circuit 202 of the second semiconductor element 2 and the second circuit 302 of the third semiconductor element 3 each construct a logic circuit, as with the first embodiment.

Furthermore, the third semiconductor element 3M is packaged alone directly in the packaging region 120 along one side on a side opposite to the arrow-X direction of the first semiconductor element 1. The third semiconductor element 3M includes the second circuit 302M, and the second circuit 302M constructs a memory circuit.

The third semiconductor element 3M is packaged in the packaging region 120 of the first semiconductor element 1 with the bump electrode 5 interposed therebetween, as with the semiconductor device 10 according to the fourth embodiment.

Components other than the above-described components are the same or substantially the same as the components of the semiconductor devices 10 according to the first embodiment and the fourth embodiment described above.

### Workings and Effects

In the semiconductor device 10 according to the fifth embodiment, it is possible to obtain workings and effects similar to the workings and effects obtained by the semiconductor device 10 according to the fourth embodiment.

### 6. Sixth Embodiment

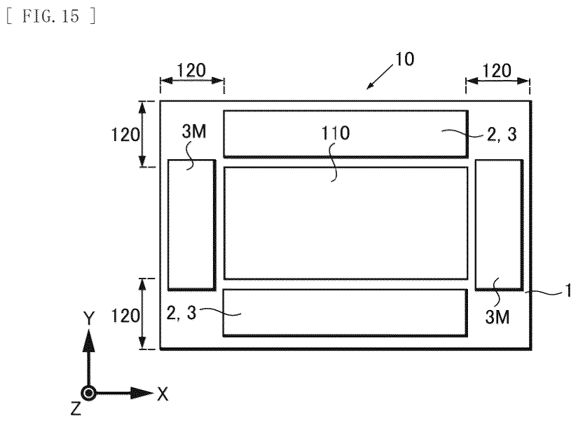

Description is given of the semiconductor device 10 according to the sixth embodiment of the present disclosure with reference to FIG. 15.

### Configuration of Semiconductor Device 10

FIG. 15 illustrates an example of a planar configuration of the semiconductor device 10 according to the sixth embodiment.

As illustrated in FIG. 15, the semiconductor device 10 according to the sixth embodiment further includes the third semiconductor element 3M in the packaging region 120 along another side on a side in the arrow-X direction of the first semiconductor element 1 in the semiconductor device 10 according to the fifth embodiment. That is, the second semiconductor element 2 and the third semiconductor element 3 are packaged in the packaging region 120 on each of sides opposed to each other in the arrow-Y direction of the first semiconductor element 1, and the third semiconductor element 3M is packaged in the packaging region 120 on each of sides opposed to each other in the arrow-X direction of the first semiconductor element 1.

Components other than the above-described components are the same or substantially the same as the components of the semiconductor devices 10 according to the first embodiment and the fifth embodiment described above.

### Workings and Effects

In the semiconductor device 10 according to the sixth embodiment, it is possible to obtain workings and effects similar to the workings and effects obtained by the semiconductor device 10 according to the fifth embodiment.

### 7. Seventh Embodiment

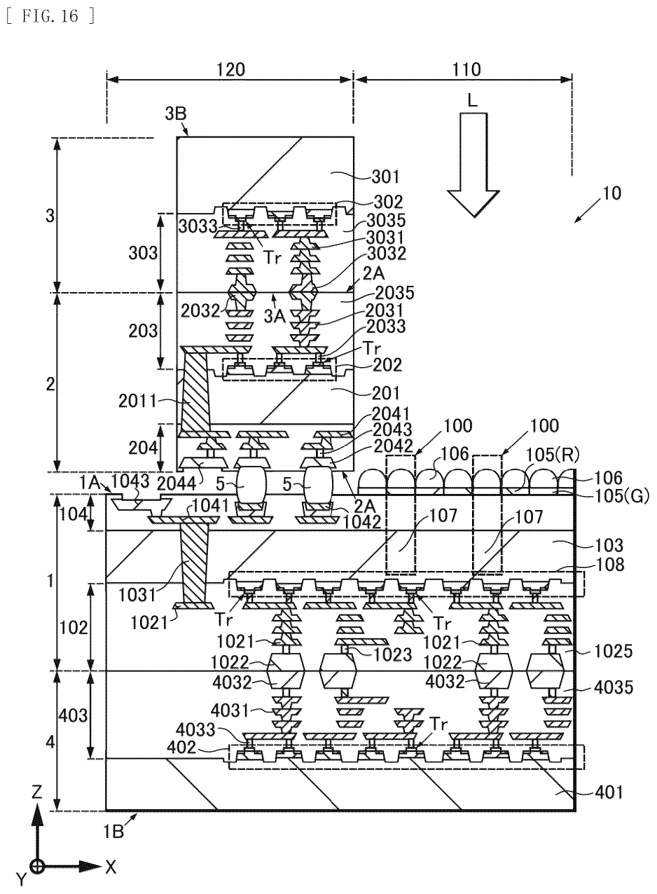

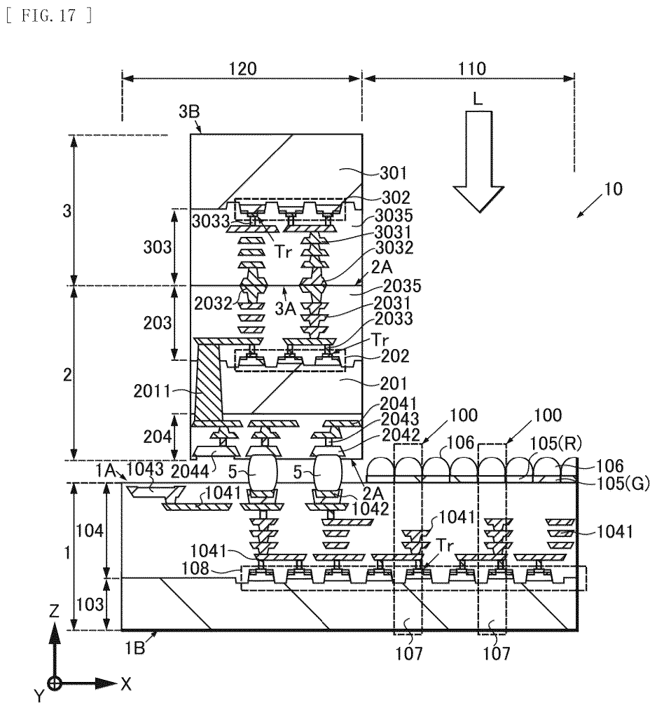

Description is given of the semiconductor device 10 according to the sixth embodiment of the present disclosure with reference to FIG. 16.

### Configuration of Semiconductor Device 10

FIG. 16 illustrates an example of a longitudinal cross-sectional configuration of the semiconductor device 10 according to the seventh embodiment.

As illustrated in FIG. 16, the semiconductor device 10 according to the seventh embodiment further includes a fourth semiconductor element 4 in the semiconductor device 10 according to the first embodiment.

Detailed description is given of this point. The semiconductor device 10 constructs a back-illuminated solid-state imaging device, as with the semiconductor device 10 according to the first embodiment. The fourth semiconductor element 4 is packaged on the side of the back surface 2B of the first semiconductor element 1. The fourth semiconductor element 4 includes a semiconductor substrate 401 and a third circuit 402.

The semiconductor substrate 401 is formed by, for example, a single-crystalline Si substrate, as with the semiconductor substrate 103 of the first semiconductor element 1.

The third circuit 402 is provided on the semiconductor substrate 401 on the side of the front surface 1A of the first semiconductor element 1. In the third circuit 402, for example, a logic circuit similar to that of the first circuit 202 or the second circuit 302 is divided, or the third circuit 402 includes another logic circuit that is not selected in the first circuit 202 or the second circuit 302. As with the pixel circuit 108, the third circuit 402 is constructed to include the transistors Tr, a resistor, a capacitor, and the like. In addition, the third circuit 402 may be a memory circuit described in the semiconductor device 10 according to the second embodiment.

A wiring layer 403 is provided on the side of the front surface 1A of the semiconductor substrate 401. A wiring 4031 with a plurality of layers and a terminal 4032 are formed in the wiring layer 403. The wiring 4031 and the terminal 4032 couple, for example, logic circuits together. For example, a metal wiring material such as Cu is used for the wiring 4031. For example, a metal wiring material such as Cu is used for the terminal 4032. In addition, a plug wiring 4033 is formed on the wiring 4031. The plug wiring 4033 is electrically coupled to the transistor Tr of the third circuit 402. For example, a metal wiring material such as W is used for the plug wiring 4033.

Although illustrated in a simplified manner, an insulator 4035 is formed, for example, between the wirings 4031 with the plurality of layers and between the wiring 4031 and the terminal 4032. The insulator 4035 is formed by, for example, a SiO₂ film.

A front surface of the terminal 4032 is exposed from the insulator 4035. The wiring 1022 of the wiring layer 102 of the first semiconductor element 1 is Cu—Cu bonded as a terminal to the terminal 4032. That is, as with a case of joining between the terminal 2032 of the second semiconductor element 2 and the terminal 3032 of the third semiconductor element 3, the terminal 4032 is mechanically and electrically coupled to the wiring 1022.

Here, the fourth semiconductor element 4 corresponds to a “fourth semiconductor element” according to the present technology. In addition, the third circuit 402 corresponds to a “third circuit” according to the present technology.

Components other than the above-described components are the same or substantially the same as the components of the semiconductor device 10 according to the first embodiment described above.

### Workings and Effects

In the semiconductor device 10 according to the seventh embodiment, it is possible to obtain workings and effects similar to the workings and effects obtained by the semiconductor device 10 according to the first embodiment.

Furthermore, the semiconductor device 10 includes the fourth semiconductor element 4 including the third circuit 402. In the semiconductor device 10 having such a configuration, further addition of the fourth semiconductor element makes it possible to expand a system configuration of the back-illuminated solid-state imaging device. In addition, the fourth semiconductor element 4 is packaged on the side of the back surface 1B of the first semiconductor element 1, which makes it possible to further improve packaging density while expanding the pixel region 110 of the semiconductor device 10.

### 8. Eighth Embodiment

Description is given of the semiconductor device 10 according to the eighth embodiment of the present disclosure with reference to FIG. 17.

### Configuration of Semiconductor Device 10

FIG. 17 illustrates an example of a longitudinal cross-sectional configuration of the semiconductor device 10 according to the eighth embodiment.

As illustrated in FIG. 17, the semiconductor device 10 according to the eighth embodiment is an application example of the semiconductor device 10 according to the first embodiment.

Detailed description is given of this point. Unlike the semiconductor device 10 according to the first embodiment, the semiconductor device 10 constructs a front-illuminated solid-state imaging device. That is, in the first semiconductor element 1, the pixel circuit 108 is provided on the side of the front surface 1A of the semiconductor substrate 103. The insulator 104 is also used as a wiring layer, and the wiring 1041 and the terminal 1042 are formed in the insulator 104.

Moreover, as with the semiconductor device 10 according to the first embodiment, the second semiconductor element 2 is packaged in the packaging region 120 of the first semiconductor element 1. In addition, the third semiconductor element 3 is packaged on the second semiconductor element 2.

Components other than the above-described components are the same or substantially the same as the components of the semiconductor device 10 according to the first embodiment described above.

### Workings and Effects

In the semiconductor device 10 according to the eighth embodiment, it is possible to obtain workings and effects similar to the workings and effects obtained by the semiconductor device 10 according to the first embodiment.

Furthermore, in the semiconductor device 10, even if the first semiconductor element 1 constructs the front-illuminated solid-state imaging device, it is possible to improve packaging density of the peripheral circuit while enlarging the pixel region 110.

### 9. Ninth Embodiment

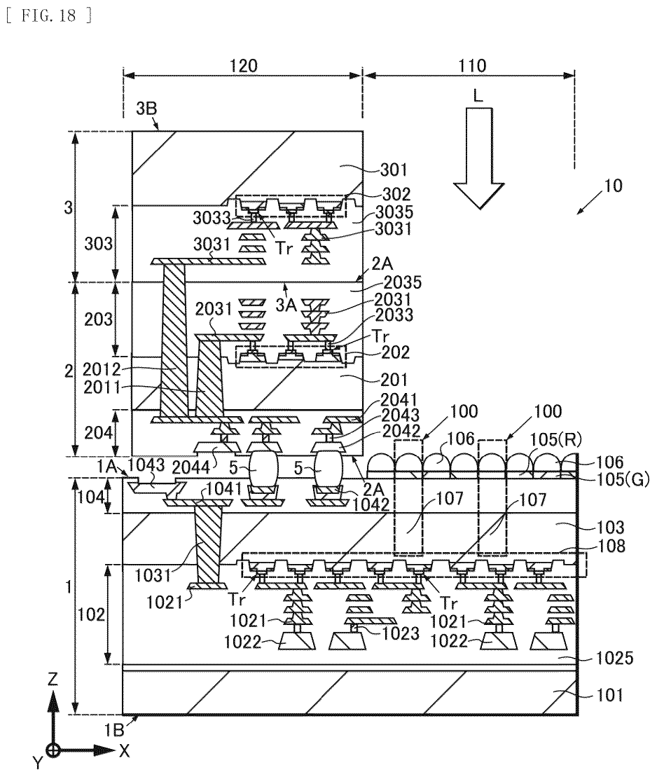

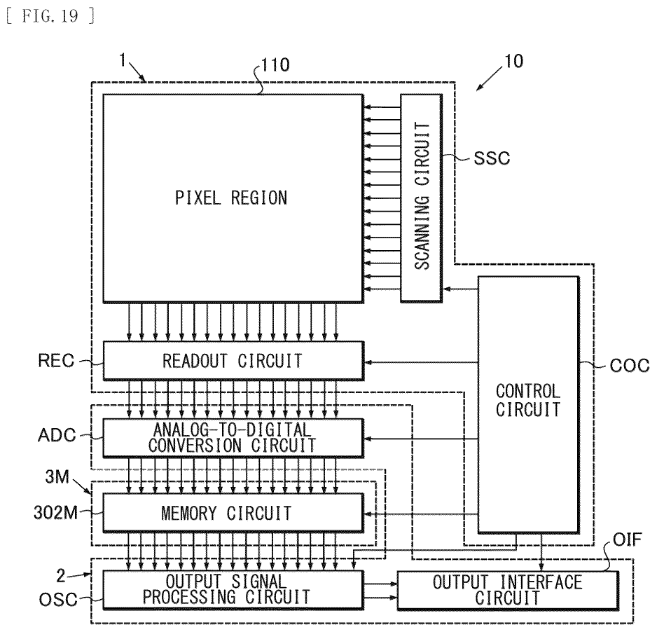

Description is given of the semiconductor device 10 according to the ninth embodiment of the present disclosure with reference to FIG. 18.

### Configuration of Semiconductor Device 10

FIG. 18 illustrates an example of a longitudinal cross-sectional configuration of the semiconductor device 10 according to the ninth embodiment.

As illustrated in FIG. 18, the semiconductor device 10 according to the ninth embodiment includes a through wiring 2012 in the second semiconductor element 2 in the semiconductor device 10 according to the first embodiment. Here, the through wiring 2012 corresponds to a “second through wiring” according to the present technology.

Detailed description is given of this point. The through wiring 2012 that penetrates the semiconductor substrate 201 and the wiring layer 203 in the thickness direction is provided in the second semiconductor element 2 of the semiconductor device 10.

An end of the through wiring 2012 is electrically coupled to the wiring 2041 provided in the wiring layer 204 of the second semiconductor element 2. The wiring 2041 is indirectly electrically coupled to the pixel 100 with the pixel circuit 108 of the first semiconductor element 1 interposed therebetween.

In addition, another end of the through wiring 2012 is electrically coupled to the terminal 3032 of the wiring layer 303 of the third semiconductor element 3. The terminal 3032 is electrically coupled to the second circuit 302 with the wiring 3031 interposed therebetween.

The through wiring 2012 is formed by a metal wiring material similar to that of the through wiring 2011. In addition, consequently, the through wiring 2012 electrically couples the wiring 2014 of the second semiconductor element 2 and the wiring 3031 of the third semiconductor element 3 to each other; therefore, it is not necessary to join the terminal 2032 of the second semiconductor element 2 and the terminal 3032 of the third semiconductor element 3 together.

Components other than the above-described components are the same or substantially the same as the components of the semiconductor device 10 according to the first embodiment described above.

### Workings and Effects

In the semiconductor device 10 according to the ninth embodiment, it is possible to obtain workings and effects similar to the workings and effects obtained by the semiconductor device 10 according to the first embodiment.

Furthermore, the semiconductor device 10 includes a through wiring 1012 that penetrates the second semiconductor element 2. In the semiconductor device 10 having such a configuration, it is possible to easily achieve an electrical coupling structure of the second semiconductor element 2 and the third semiconductor element 3.

### 10. Tenth Embodiment

Description is given of the semiconductor device 10 according to the tenth embodiment of the present disclosure with reference to FIG. 19. In the semiconductor device 10 according to the tenth embodiment to the semiconductor device 10 according to the thirteenth embodiment of the present disclosure to be described later, an example is described in which an optimal system configuration is constructed.

### System Configuration of Semiconductor Device 10

FIG. 19 illustrates an example of a system configuration of the semiconductor device 10 according to the tenth embodiment.

As illustrated in FIG. 19, the semiconductor device 10 according to the tenth embodiment, includes the pixel region 110, a scanning circuit SSC, a readout circuit REC, and a control circuit COC in the first semiconductor element 1 in the semiconductor device 10 according to the second embodiment.

The scanning circuit SSC includes one or more selected from, for example, a vertical drive circuit and a horizontal drive circuit. In addition, the readout circuit REC includes the pixel circuit 108 that reads a pixel signal converted from light into electric charge in the pixel 100.

The first circuit 202 provided in the second semiconductor element 2 includes an analog-to-digital conversion circuit ADC, an output signal processing circuit OSC, and an output interface circuit OIF. Moreover, the second circuit 302M of the third semiconductor element 3M includes a memory circuit.

In the analog-to-digital conversion circuit ADC, the pixel signal read by the readout circuit REC is converted from an analog signal to a digital signal. The pixel signal converted into the digital signal is temporarily held in the memory circuit. In other words, the pixel signal is temporarily stored in the memory circuit.

The output signal processing circuit OSC reads the pixel signal held by the memory circuit, and converts the pixel signal into a predetermined output signal. The output interface circuit OIF outputs the output signal to an external device.

Components other than the above-described components are the same or substantially the same as the components of the semiconductor device 10 according to the second embodiment described above.

### Workings and Effects

In the semiconductor device 10 according to the tenth embodiment, it is possible to obtain workings and effects similar to the workings and effects obtained by the semiconductor device 10 according to the second embodiment.

In addition, as illustrated in FIG. 19, the semiconductor device 10 includes the pixel region 110, the scanning circuit SSC, the readout circuit REC, and the control circuit COC in the first semiconductor element 1. Moreover, the semiconductor device 10 includes the analog-to-digital conversion circuit ADC, the output signal processing circuit OSC, and the output interface circuit OIF in the second semiconductor element 2, and includes the memory circuit in the third semiconductor element 3M.

Accordingly, it is possible to produce the third semiconductor element 3M by a process specific to a memory device independent of the first semiconductor element 1 and the second semiconductor element 2. To describe this in detail, it is possible to construct the third semiconductor element 3M as a semiconductor element using a special material such as a high-dielectric constant material or a magnetic material and a special process. Specifically, it is possible to mount a memory circuit such as a volatile semiconductor storage element (for example, a DRAM: Dynamic Random Access Memory), a magneto-resistive memory (a MRAM: Magneto-resistive Random Access Memory), or a resistive random access memory (a RRAM: Resistive Random access Memory) in the third semiconductor element 3M.

In the tenth embodiment, providing the memory circuit in the third semiconductor element 3M makes it possible to construct an optimal system configuration. For example, a special material and a special process are used for the memory circuit; therefore, in the third semiconductor element 3M, no through wiring is formed in the semiconductor substrate 301 (refer to FIG. 9). That is, the through wiring is an addition of a new structure, in addition to the special material and the special process. Accordingly, it is possible to effectively suppress or prevent deterioration in characteristic of a memory element of the memory circuit due to formation of the through wiring.

In the semiconductor device 10 having such a configuration, the through wiring 2011 is used for coupling between the first semiconductor element 1 and the second semiconductor element 2 (for example, refer to FIG. 9). Moreover, coupling between the terminal 2032 and the terminal 3032 is used for coupling between the second semiconductor element 2 and the third semiconductor element 3M (for example, refer to FIG. 9).

It is to be noted that it is possible to appropriately mount a circuit other than the memory circuit in any of the first semiconductor element 1 and the second semiconductor element 2.

### 11. Eleventh Embodiment

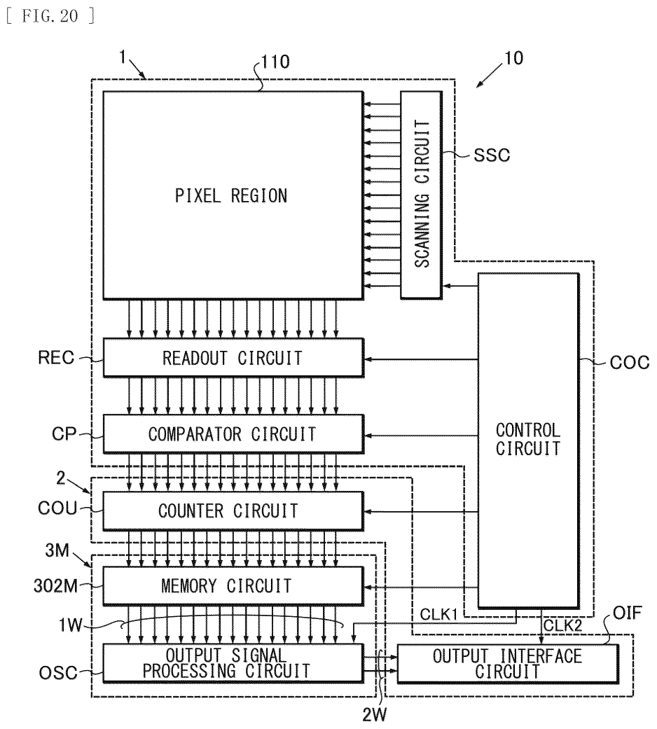

Description is given of the semiconductor device 10 according to the eleventh embodiment of the present disclosure with reference to FIG. 20. The semiconductor device 10 according to the eleventh embodiment is an application example of the semiconductor device 10 according to the tenth embodiment.

### System Configuration of Semiconductor Device 10

FIG. 20 illustrates an example of a system configuration of the semiconductor device 10 according to the eleventh embodiment.

As illustrated in FIG. 20, in the semiconductor device 10 according to the eleventh embodiment, the analog-to-digital conversion circuit ADC in the semiconductor device 10 according to the tenth embodiment is divided into a comparator circuit CP and a counter circuit COU. The comparator circuit CP is mounted in the first semiconductor element 1. In addition, the counter circuit COU is mounted as the first circuit 202 in the second semiconductor element 2. Furthermore, the second semiconductor element 2 includes the output interface circuit OIF as the first circuit 202.

Moreover, the third semiconductor element 3M includes a memory circuit as the second circuit 302M, and further includes the output signal processing circuit OSC.

Here, the output signal processing circuit OSC is electrically coupled to the memory circuit through the wiring 3031 (refer to FIG. 9; hereinafter simply referred to as a “first wiring 1W”). The first wiring 1W corresponds to a “first wiring” according to the present technology. The output signal processing circuit OSC operates by a first clock signal CLK1 supplied from the control circuit COC.

In addition, the output interface circuit OIF is electrically coupled to the output signal processing circuit OSC through the wiring 3031 and the wiring 2031 (refer to FIG. 9; hereinafter simply referred to as a “second wiring 2W”). The second wiring 2W corresponds to a “second wiring” according to the present technology. The output interface circuit OIF operates by a second clock signal CLK2 supplied from the control circuit COC.

Here, the number of second wirings 2W is smaller than the number of first wirings 1W. In addition, a clock frequency of the second clock signal CLK2 is higher than a clock frequency of the first clock signal CLK1. That is, it is possible to transfer a large number of signals between the memory circuit and the output signal processing circuit OSC by parallel processing. High-speed serial transfer of signals is possible between the output signal processing circuit OSC and the output interface circuit OIF.

Components other than the above-described components are the same or substantially the same as the components of the semiconductor device 10 according to the tenth embodiment described above.

### Workings and Effects

In the semiconductor device 10 according to the eleventh embodiment, it is possible to obtain workings and effects similar to the workings and effects obtained by the semiconductor device 10 according to the tenth embodiment.

In addition, in the semiconductor device 10, as illustrated in FIG. 20, the memory circuit and the output signal processing circuit OSC are provided in the third semiconductor element 3. Operations of the memory circuit and the output signal processing circuit OSC are not synchronized with a cycle of a series of row-sequential readout operations in which the pixels 100 (refer to FIG. 9) are selected row by row by the vertical scanning circuit, the pixel signals from the selected pixels 100 are read, and the pixel signals are then converted from analog signals to digital signals. That is, the memory circuit and the output signal processing circuit OSC operate as random logic circuits. This causes generation of irregular power supply noise.

A generation source of such power supply noise is provided in the third semiconductor element 3 far from the pixels 100, which makes it possible to effectively suppress or prevent generation of the power supply noise. Accordingly, as the solid-state imaging device, it is possible to achieve favorable image quality.

In addition, in the semiconductor device 10, as illustrated in FIG. 20, the output interface circuit OIF is provided in the second semiconductor element 2. The second semiconductor element 2 is packaged in proximity to the first semiconductor element 1 including the terminal 1043 (refer to FIG. 9) to be used as a terminal for inspection or an external output terminal. Accordingly, it is possible to effectively reduce a parasitic resistance and a parasitic capacitance added to a signal output path from the output interface circuit OIF to the external output terminal. In addition, the output interface circuit OIF operates by the high-speed second clock signal CLK2.

In the semiconductor device 10 having such a configuration, it is possible to achieve higher speed of signal transfer.

Furthermore, in the semiconductor device 10, as illustrated in FIG. 20, the analog-to-digital conversion circuit ADC is divided into the comparator circuit CP and the counter circuit COU. The comparator circuit CP is an analog circuit, and is mounted in the first semiconductor element 1. In addition, the counter circuit COU is a digital circuit, and is mounted in the second semiconductor element 2.

The second semiconductor element 2 having such a configuration includes only a circuit block of the digital circuit; therefore, an element of the analog circuit is not necessary, and it is possible to easily implement the circuit block. As a result, it is possible to reduce production cost of the second semiconductor element 2.

### 12. Twelfth Embodiment

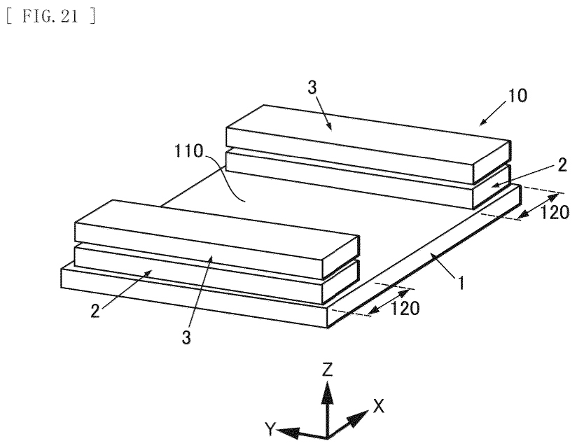

Description is given of the semiconductor device 10 according to the twelfth embodiment of the present disclosure with reference to FIG. 21. The semiconductor device 10 according to the twelfth embodiment is an application example of the semiconductor device 10 according to the tenth embodiment.

### System Configuration of Semiconductor Device 10

FIG. 21 illustrates an example of a schematic configuration of the semiconductor device 10 according to the twelfth embodiment.

As illustrated in FIG. 21, in the semiconductor device 10 according to the twelfth embodiment, the readout circuit REC and the analog-to-digital conversion circuit ADC are distributed and mounted in both the second semiconductor element 2 and the third semiconductor element 3 in the semiconductor device 10 according to the tenth embodiment. In other words, it is possible to mount twice as many analog-to-digital conversion circuits AD within a predetermined area of the packaging region 120 of the first semiconductor element 1 in a plan view.

Components other than the above-described components are the same or substantially the same as the components of the semiconductor device 10 according to the tenth embodiment described above.

### Workings and Effects

In the semiconductor device 10 according to the twelfth embodiment, it is possible to obtain workings and effects similar to the workings and effects obtained by the semiconductor device 10 according to the tenth embodiment.

In addition, in the semiconductor device 10, as illustrated in FIG. 21, the readout circuit REC and the analog-to-digital conversion circuit ADC are distributed and mounted in both the second semiconductor element 2 and the third semiconductor element 3. Accordingly, it is possible to double readout speed of the pixel signals without enlarging a chip size of the semiconductor device 10.

In addition, in the semiconductor device 10, it is possible to produce each of the second semiconductor element 2 and the third semiconductor element 3 by the same structure, which makes it possible to reduce production cost. Here, the term “produced by the same structure” is used to mean that each of the second semiconductor element 2 and the third semiconductor element 3 is produced by exactly the same design, development, and manufacturing.

It is to be noted that the twelfth embodiment is an example in which the readout circuits REC and the analog-to-digital conversion circuits ADC are provided in parallel in the respective second and third semiconductor elements 2 and 3. In the present technology, the readout circuit REC may be mounted in the first semiconductor element 1, and the analog-to-digital conversion circuits ADC may be provided in parallel in the respective second and third semiconductor elements 2 and 3.

### 13. Thirteenth Embodiment

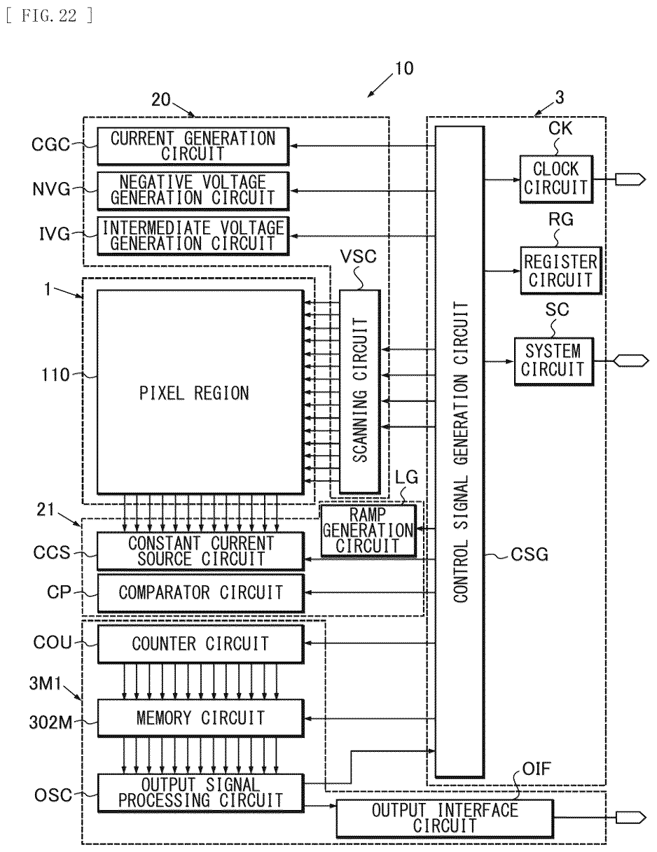

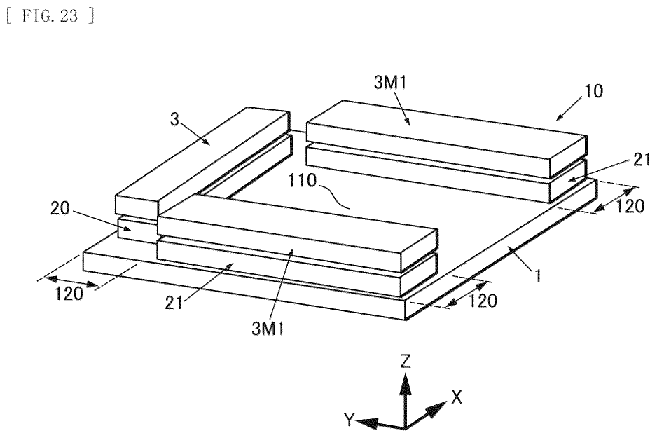

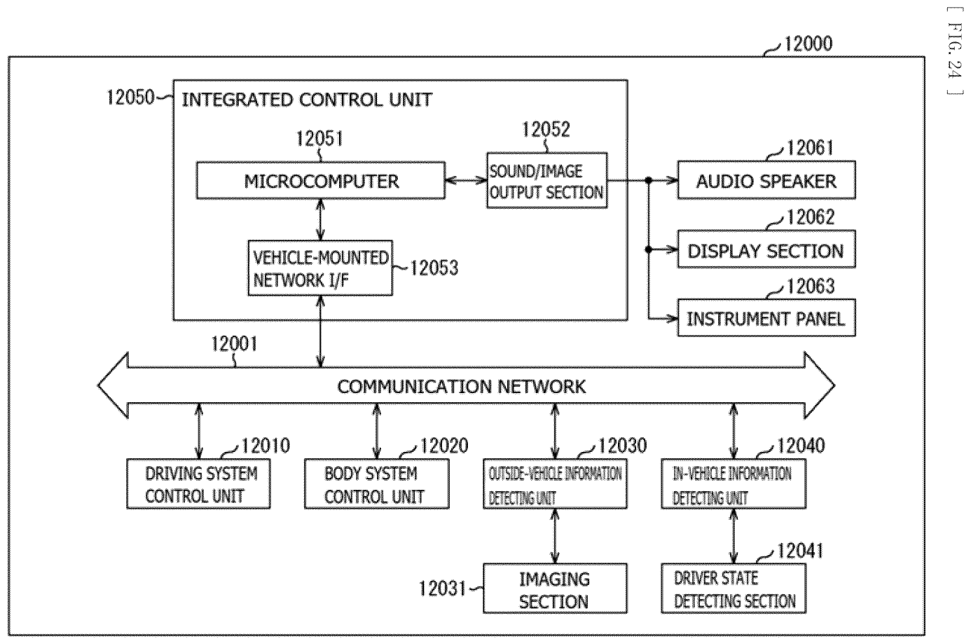

Description is given of the semiconductor device 10 according to the thirteenth embodiment of the present disclosure with reference to FIGS. 22 and 23. The semiconductor device 10 according to the thirteenth embodiment is an application example of the semiconductor device 10 according to the eleventh embodiment.

### System Configuration of Semiconductor Device 10

FIG. 22 illustrates an example of a system configuration of the semiconductor device 10 according to the thirteenth embodiment.

As illustrated in FIG. 22, the semiconductor device 10 according to the thirteenth embodiment includes the first semiconductor element 1, a second semiconductor element 20 and a second semiconductor element 21, and the third semiconductor element 3 and a third semiconductor element 3M1.

The first semiconductor element 1 includes the pixel region 110.

A current generation circuit CGC, a negative voltage generation circuit NVG, an intermediate voltage generation circuit IVG, and a vertical scanning circuit VSC are mounted as the first circuit 202 in the second semiconductor element 20. The current generation circuit CGC and the like mounted in the second semiconductor element 20 are analog circuits.

In addition, a constant current source circuit CCS, the comparator circuit CP, and a ramp generation circuit LG are mounted as the first circuit 202 in the second semiconductor element 21. The constant current source circuit CCS and the like mounted in the second semiconductor element 21 are analog circuits, as with the second semiconductor element 20.

A control signal generation circuit CSG, a clock generation circuit CK, a system circuit SC, and a register circuit RG are mounted as the second circuit 302 in the third semiconductor element 3. The control signal generation circuit CSG and the like mounted in the third semiconductor element 3 are digital circuits.

A memory circuit, the counter circuit COU, the output signal processing circuit OSC, and the output interface circuit OIF are mounted as the second circuit 302M in the third semiconductor element 3M1. The memory circuit and the like mounted in the third semiconductor element 3M1 are digital circuits.

Here, the control signal generation circuit CSG supplies a divided clock signal to each of the current generation circuit CGC, the negative voltage generation circuit NVG, and the intermediate voltage generation circuit IVG. In addition, the control signal generation circuit CSG supplies a row selection signal, a shutter address signal, a read address signal, a latch pulse signal, a reset pulse signal, and the like to the vertical scanning circuit VSC. In addition, the control signal generation circuit CSG supplies a control pulse signal to each of the constant current source circuit CCS and the comparator circuit CP, and supplies a SYNC signal to the memory circuit.

Furthermore, the control signal generation circuit CSG supplies a register reflection signal to the register circuit RG, and supplies an interrupt signal to the system circuit SC through an advanced peripheral bus (APB) and an interface (IF).

### Configuration of Semiconductor Device 10

FIG. 23 illustrates an example of a schematic configuration of the semiconductor device 10 illustrated in FIG. 22.

As illustrated in FIG. 23, the second semiconductor element 21 and the third semiconductor element 3M1 are stacked and packaged in each of the packaging regions 120 opposed to each other in the arrow-X direction of the first semiconductor element 1.

Furthermore, the second semiconductor element 20 and the third semiconductor element 3 are stacked and packaged in the packaging region 120 in the arrow-Y direction of the first semiconductor element 1.

Components other than the above-described components are the same or substantially the same as the components of the semiconductor device 10 according to the eleventh embodiment described above.

### Workings and Effects

In the semiconductor device 10 according to the thirteenth embodiment, it is possible to obtain workings and effects similar to the workings and effects obtained by the semiconductor device 10 according to the eleventh embodiment.

In addition, in the semiconductor device 10, as illustrated in FIGS. 22 and 23, the pixel region 110 is provided in the first semiconductor element 1. Moreover, analog circuits are provided in the second semiconductor element 20 and the second semiconductor element 21, and digital circuits are provided in the third semiconductor element 3 and the third semiconductor element 3M1.

In the thirteenth embodiment, the system circuit SC and the clock generation circuit CK that control the entirety of the semiconductor device 10 are provided in the third semiconductor element 3. Accordingly, in order to supply a control signal and a clock signal to a digital circuit other than the above-described ones of the third semiconductor element 3, the analog circuits of the second semiconductor element 2, or the like, a structure is necessary in which the signals pass through each of the second semiconductor element 2 and the first semiconductor element 1 once from the third semiconductor element 3.

In the semiconductor device 10 having such a configuration, the first semiconductor element 1 has a structure dedicated to pixels, and is produced by a process dedicated to pixels. Likewise, the second semiconductor element 20 and the second semiconductor element 21 each have a structure dedicated to analog circuits, and are produced by a process dedicated to analog circuits. Moreover, the third semiconductor element 3 and the third semiconductor element 3M1 each have a structure dedicated to digital circuits, and are produced by a process dedicated to digital circuits. That is, the first semiconductor element 1, the second semiconductor element 20 and the second semiconductor element 21, and the third semiconductor element 3 and the third semiconductor element 3M1 have device structures completely independent of each other, and are produced by semiconductor manufacturing processes completely independent of each other.

Accordingly, in the first semiconductor element 1, it is possible to adopt a structure specific to a pixel characteristic and adopt a process specific to the pixel characteristic. In addition, in each of the second semiconductor element 20 and the second semiconductor element 21, it is possible to adopt, for example, a structure specific to high withstand voltage and low noise and adopt a process specific to high withstand voltage and low noise. Furthermore, in each of the third semiconductor element 3 and the third semiconductor element 3M1, it is possible to adopt a structure specific to low voltage and miniaturization and adopt a process specific to low voltage and miniaturization.

That is, it is possible to independently optimize each semiconductor element, and it is possible to improve performance of the entire semiconductor device 10.

### 14. Example of Application to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

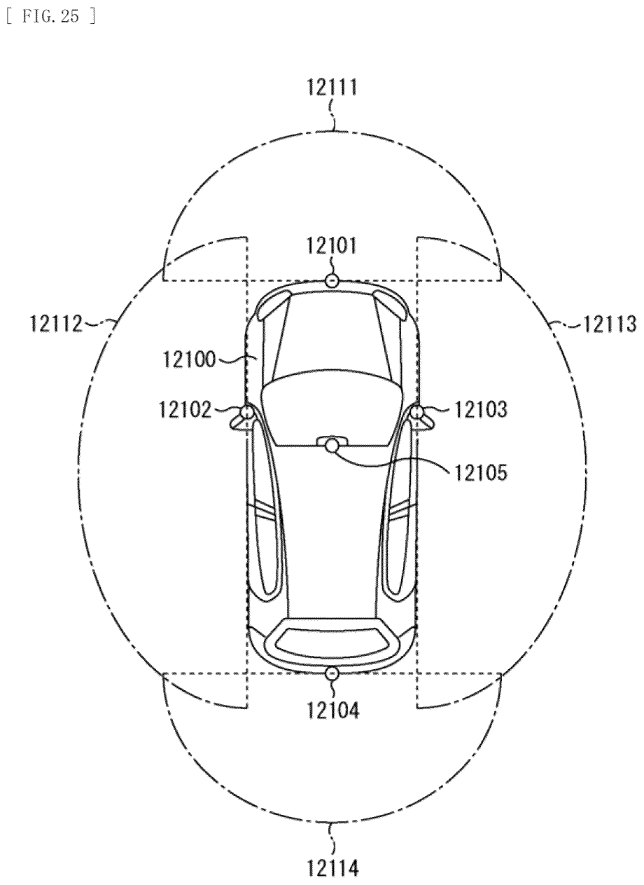

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to the present disclosure may be applied. The technology according to the present disclosure may be applied to the imaging section 12031 among the configurations described above. The application of the technology according to the present disclosure to the imaging section 12031 enables achievement of the imaging section 12031 that makes it possible to improve packaging density of the peripheral circuit while enlarging the pixel region.

### 15. Other Embodiments

The present technology is not limited to the embodiments described above, and various modifications may be made without departing from the gist of the present technology.

For example, the semiconductor devices according to two or more embodiments, among the solid-state semiconductor devices according to the foregoing first to ninth embodiments, may be combined.

In addition, in the present technology, three or more semiconductor elements may be stacked and packaged in a packaging region of a first semiconductor element. In this case, a semiconductor substrate of a semiconductor element stacked closer to the first semiconductor element than a semiconductor element stacked in an uppermost layer is thinned.

Furthermore, the present technology is applicable to a semiconductor device that includes the first semiconductor element including a pixel region in which a plurality of pixels each having a light-emitting source are arranged. The light-emitting source emits light. Here, examples of the light-emitting source include a light-emitting diode (LED), a laser, a liquid crystal including a backlight, an organic electroluminescence (EL), a plasma, and the like.

A semiconductor device according to a first aspect of the present disclosure includes a first semiconductor element, a second semiconductor element, and a third semiconductor element.

The first semiconductor element includes a pixel region in which a plurality of pixels is arranged on one surface. The second semiconductor element is packaged in a region different from the pixel region on the one surface, and includes a first circuit that is electrically coupled to the pixel. The third semiconductor element is packaged on the second semiconductor element on a side opposite to the first semiconductor element, and includes a second circuit that is electrically coupled to the pixel.

In the semiconductor device having such a configuration, the second semiconductor element and the third semiconductor element are stacked in the region different from the pixel region, which makes it possible to improve packaging density in a thickness direction of the first semiconductor element. Accordingly, it is possible to improve packaging density of a peripheral circuit including the first circuit and the second circuit while enlarging the pixel region.

In addition, in a semiconductor device according to a second aspect of the present disclosure, a semiconductor substrate of the second semiconductor element has a thinner thickness than a thickness in a same direction of a semiconductor substrate of the third semiconductor element in the semiconductor device according to the first aspect

In the semiconductor device having such a configuration, it is possible to easily process the semiconductor substrate of the second semiconductor element, which makes it possible to form, for example, a through wiring that penetrates the semiconductor substrate in the thickness direction. Accordingly, it is possible to package each of the second semiconductor element and the third semiconductor element on the first semiconductor element in a stacked state, which makes it possible to improve packaging density in the packaging region while enlarging the pixel region.

### Configuration of Present Technology

The present technology has the following configurations. According to the present technology having the following configurations, it is possible, in a semiconductor device, to improve packaging density in a packaging region while enlarging a pixel region.
(1)

A semiconductor device including:
a first semiconductor element including a pixel region in which a plurality of pixels is arranged on one surface;
a second semiconductor element packaged in a region different from the pixel region on the one surface, and including a first circuit that is electrically coupled to the pixel; and
a third semiconductor element packaged on the second semiconductor element on a side opposite to the first semiconductor element, and including a second circuit that is electrically coupled to the pixel.
(2)

The semiconductor device according to (1), in which a plane area of each of the second semiconductor element and the third semiconductor element is smaller than a plane area of the first semiconductor element, as viewed in a thickness direction of the first semiconductor element.
(3)

The semiconductor device according to (2), in which each of the second semiconductor element and the third semiconductor element is provided within the one surface of the first semiconductor element, as viewed in the thickness direction of the first semiconductor element.
(4)

The semiconductor device according to any one of (1) to (3), in which a thickness of a semiconductor substrate of the second semiconductor element is thinner than a thickness of a semiconductor substrate in a same direction of the third semiconductor element.
(5)

The semiconductor device according to any one of (1) to (4), in which the second semiconductor element includes a first through wiring that penetrates in a thickness direction and electrically couples the pixel and the first circuit to each other.
(6)

The semiconductor device according to any one of (1) to (5), in which the second semiconductor element includes a second through wiring that penetrates in a thickness direction and electrically couples the pixel and the second circuit to each other,
(7)

The semiconductor device according to any one of (1) to (6), in which
a first terminal that is electrically coupled to the pixel is included on a side of the one surface in the first semiconductor element,
a second terminal that is electrically coupled to the first circuit or the second circuit is included on a side of the first semiconductor element in the second semiconductor element, and
the second terminal is electrically coupled to the first terminal with a bump electrode interposed therebetween.
(8)

The semiconductor device according to any one of (1) to (5) and (7), in which
a third terminal that is electrically coupled to the first circuit is included on a side of the third semiconductor element in the second semiconductor element,
a fourth terminal that is electrically coupled to the second circuit is included on a side of the second semiconductor element in the third semiconductor element, and
the fourth terminal is opposed to and joined to the third terminal, and the third terminal and the fourth terminal are electrically coupled to each other.
(9)

The semiconductor device according to any one of (1) to (8), in which the first semiconductor element constructs a front-illuminated solid-state imaging device.
(10)

The semiconductor device according to any one of (1) to (8), in which the first semiconductor element constructs a back-illuminated solid-state imaging device.
(11)

The semiconductor device according to any one of (1) to (8), in which
a fourth semiconductor element is provided on a side opposite to the one surface of the first semiconductor element, the fourth semiconductor element including a third circuit that is electrically coupled to the pixel, and having a plane area equal to a plane area of the first semiconductor element, as viewed in a thickness direction of the first semiconductor element, and
the first semiconductor element constructs a back-illuminated solid-state imaging device.
(12)

The semiconductor device according to any one of (1) to (11), in which the first circuit and the second circuit include logic circuits.
(13)

The semiconductor device according to any one of (1) to (11), in which
the first circuit includes a logic circuit, and
the second circuit includes a memory circuit.
(14)

The semiconductor device according to any one of (1) to (13), in which
a fifth semiconductor element is packaged in a region different from the pixel region and a region in which the second semiconductor element is packaged on the one surface of the first semiconductor element, the fifth semiconductor element including a fourth circuit that is electrically coupled to the pixel.
(15)

The semiconductor device according to (14), in which the fourth circuit includes a memory circuit.
(16)

The semiconductor device according to any one of (1) to (15), in which
the first semiconductor element is formed in a rectangular shape, as viewed in a thickness direction, and
the pixel region is provided in a middle portion of the one surface of the first semiconductor element, and the second semiconductor element and the third semiconductor element are packaged in a peripheral portion along at least one side of the rectangular shape.
(17)

The semiconductor device according to (13), in which the second circuit of the third semiconductor element includes the memory circuit that temporarily holds a result of analog-to-digital conversion of a pixel signal outputted from the pixel.
(18)

The semiconductor device according to (13) or (17), further including:
an output signal processing circuit that is electrically coupled to the memory circuit through a plurality of first wirings and operates by a first clock signal, in which
the memory circuit and the output signal processing circuit are provided in the third semiconductor element.
(19)

The semiconductor device according to (18), further including:
an output interface circuit that is electrically coupled to the output signal processing circuit through a plurality of second wirings, and operates by a second clock signal, the second wirings being smaller in number than the first wirings, and the second clock signal having a higher clock frequency than a clock frequency of the first clock signal, in which
the output interface circuit is provided as the first circuit in the second semiconductor element.
(20)

The semiconductor device according to any one of (1) to (19), further including an analog-to-digital conversion circuit that is provided in each of the first circuit of the second semiconductor element and the second circuit of the third semiconductor element.
(21)

The semiconductor device according to any one of (1) to (19), in which
an analog circuit is provided in the first circuit of the second semiconductor element, and
a digital circuit is provided in the second circuit of the third semiconductor element.

The present application claims the benefit of Japanese Priority Patent Application JP 2022-167873 filed with the Japan Patent Office on Oct. 19, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a first semiconductor element including a pixel region in which a plurality of pixels is arranged on one surface;
a second semiconductor element packaged in a region different from the pixel region on the one surface, and including a first circuit that is electrically coupled to the pixel; and
a third semiconductor element packaged on the second semiconductor element on a side opposite to the first semiconductor element, and including a second circuit that is electrically coupled to the pixel.

2. The semiconductor device according to claim 1, wherein a plane area of each of the second semiconductor element and the third semiconductor element is smaller than a plane area of the first semiconductor element, as viewed in a thickness direction of the first semiconductor element.

3. The semiconductor device according to claim 2, wherein each of the second semiconductor element and the third semiconductor element is provided within the one surface of the first semiconductor element, as viewed in the thickness direction of the first semiconductor element.

4. The semiconductor device according to claim 1, wherein a thickness of a semiconductor substrate of the second semiconductor element is thinner than a thickness of a semiconductor substrate in a same direction of the third semiconductor element.

5. The semiconductor device according to claim 4, wherein the second semiconductor element includes a first through wiring that penetrates in a thickness direction and electrically couples the pixel and the first circuit to each other.

6. The semiconductor device according to claim 4, wherein the second semiconductor element includes a second through wiring that penetrates in a thickness direction and electrically couples the pixel and the second circuit to each other.

7. The semiconductor device according to claim 1, wherein
a first terminal that is electrically coupled to the pixel is included on a side of the one surface in the first semiconductor element,
a second terminal that is electrically coupled to the first circuit or the second circuit is included on a side of the first semiconductor element in the second semiconductor element, and
the second terminal is electrically coupled to the first terminal with a bump electrode interposed therebetween.

8. The semiconductor device according to claim 1, wherein
a third terminal that is electrically coupled to the first circuit is included on a side of the third semiconductor element in the second semiconductor element,
a fourth terminal that is electrically coupled to the second circuit is included on a side of the second semiconductor element in the third semiconductor element, and
the fourth terminal is opposed to and joined to the third terminal, and the third terminal and the fourth terminal are electrically coupled to each other.

9. The semiconductor device according to claim 1, wherein the first semiconductor element constructs a front-illuminated solid-state imaging device.

10. The semiconductor device according to claim 1, wherein the first semiconductor element constructs a back-illuminated solid-state imaging device.

11. The semiconductor device according to claim 1, wherein
a fourth semiconductor element is provided on a side opposite to the one surface of the first semiconductor element, the fourth semiconductor element including a third circuit that is electrically coupled to the pixel, and having a plane area equal to a plane area of the first semiconductor element, as viewed in a thickness direction of the first semiconductor element, and
the first semiconductor element constructs a back-illuminated solid-state imaging device.

12. The semiconductor device according to claim 1, wherein the first circuit and the second circuit comprise logic circuits.

13. The semiconductor device according to claim 1, wherein
the first circuit comprises a logic circuit, and
the second circuit comprises a memory circuit.

14. The semiconductor device according to claim 1, wherein
a fifth semiconductor element is packaged in a region different from the pixel region and a region in which the second semiconductor element is packaged on the one surface of the first semiconductor element, the fifth semiconductor element including a fourth circuit that is electrically coupled to the pixel.

15. The semiconductor device according to claim 14, wherein the fourth circuit comprises a memory circuit.

16. The semiconductor device according to claim 1, wherein
the first semiconductor element is formed in a rectangular shape, as viewed in a thickness direction, and
the pixel region is provided in a middle portion of the one surface of the first semiconductor element, and the second semiconductor element and the third semiconductor element are packaged in a peripheral portion along at least one side of the rectangular shape.

17. The semiconductor device according to claim 13, wherein the second circuit of the third semiconductor element comprises the memory circuit that temporarily holds a result of analog-to-digital conversion of a pixel signal outputted from the pixel.

18. The semiconductor device according to claim 13, further comprising:
an output signal processing circuit that is electrically coupled to the memory circuit through a plurality of first wirings and operates by a first clock signal, wherein
the memory circuit and the output signal processing circuit are provided in the third semiconductor element.

19. The semiconductor device according to claim 18, further comprising:
an output interface circuit that is electrically coupled to the output signal processing circuit through a plurality of second wirings, and operates by a second clock signal, the second wirings being smaller in number than the first wirings, and the second clock signal having a higher clock frequency than a clock frequency of the first clock signal, wherein
the output interface circuit is provided as the first circuit in the second semiconductor element.

20. The semiconductor device according to claim 1, further comprising an analog-to-digital conversion circuit that is provided in each of the first circuit of the second semiconductor element and the second circuit of the third semiconductor element.
